(19) United States
(12) Patent Application Publication
(10) Pub. No.: US 2024/0339477 A1
(43) Pub. Date: Oct. 10, 2024

(54) SEMICONDUCTOR DEVICE, PHOTOELECTRIC CONVERSION SYSTEM, MOVABLE OBJECT

(71) Applicant: CANON KABUSHIKI KAISHA, Tokyo (JP)

(72) Inventors: AKIRA OSETO, Chiba (JP); NOBUAKI KAKINUMA, Tokyo (JP)

(21) Appl. No.: 18/747,961

(22) Filed: Jun. 19, 2024

Related U.S. Application Data
(63) Continuation of application No. PCT/JP2022/046021, filed on Dec. 14, 2022.

(30) Foreign Application Priority Data
Dec. 22, 2021 (JP) 2021-208537
Nov. 25, 2022 (JP) 2022-188492

(51) Int. Cl. H01L 27/146; H04N 25/60

(52) U.S. Cl. CPC H01L 27/14636; H01L 27/14614; H04N 25/60

(57) ABSTRACT

A semiconductor device includes a first semiconductor substrate, a second semiconductor substrate stacked on the first semiconductor substrate, a first pad to which a first power supply voltage for driving an element on the first semiconductor substrate is externally input, a second pad to which a second power supply voltage for driving an element on the second semiconductor substrate is externally input, a first protection circuit disposed on the first semiconductor substrate, and a second protection circuit disposed on the second semiconductor substrate, wherein the first power supply voltage is higher than the second power supply voltage, wherein the first protection circuit is electrically connected to the first pad, and wherein the second protection circuit is electrically connected to the second pad.

### CROSS-REFERENCE TO RELATED APPLICATIONS

This application is a Continuation of International Patent Application No. PCT/JP2022/046021, filed Dec. 14, 2022, which claims the benefit of Japanese Patent Applications No. 2021-208537, filed Dec. 22, 2021, and No. 2022-188492, filed Nov. 25, 2022, all of which are hereby incorporated by reference herein in their entirety.

### BACKGROUND OF THE INVENTION

### Field of the Invention

The present invention relates to a semiconductor device, a photoelectric conversion system, and a movable object.

### Background Art

A semiconductor device with a plurality of stacked substrates on which protection circuits are formed to discharge external noise, such as externally applied static electricity, through appropriate paths, so that the likelihood of breakdown is reduced has been proposed.

Some semiconductor devices are configured by stacking a substrate with elements to be driven by a high voltage (hereinafter, such a substrate is also referred to as “high-voltage substrate”) and a substrate with elements to be driven by a low voltage (hereinafter, such a substrate is also referred to as “low-voltage substrate”). Patent Literature 1 proposes a device configuration with an electrostatic protection circuit formed only on one of the stacked substrates.

### CITATION LIST

### Patent Literature

PTL 1: Japanese Patent Laid-Open No. 2013-182941

In a case where protection circuits are formed only on a low-voltage substrate of a semiconductor device configured by layering a high-voltage substrate and the low-voltage substrate as discussed in Japanese Patent Application Laid-Open No. 2013-182941, an electrostatic protection circuit for the high-voltage substrate is also formed on the low-voltage substrate. Consequently, a high voltage for driving elements driven by high voltage is applied to the low-voltage substrate and wiring placed on the low-voltage substrate, and this may cause a decrease in wiring reliability and a breakdown of a pn junction. On the other hand, forming a protection circuit only on the high-voltage substrate may cause an increase in circuit area.

### SUMMARY OF THE INVENTION

According to an aspect of the present invention, a semiconductor device includes a first semiconductor substrate, a second semiconductor substrate stacked on the first semiconductor substrate, a first pad to which a first power supply voltage for driving an element on the first semiconductor substrate is externally input, a second pad to which a second power supply voltage for driving an element on the second semiconductor substrate is externally input, a first protection circuit disposed on the first semiconductor substrate, and a second protection circuit disposed on the second semiconductor substrate, wherein the first power supply voltage is higher than the second power supply voltage, wherein the first protection circuit is electrically connected to the first pad, and wherein the second protection circuit is electrically connected to the second pad.

Further features of the present invention will become apparent from the following description of exemplary embodiments with reference to the attached drawings.

### BRIEF DESCRIPTION OF THE DRAWINGS

FIG. 1 is an equivalent circuit diagram illustrating a semiconductor device according to a first exemplary embodiment.

FIG. 2A is a plan view illustrating the semiconductor device according to the first exemplary embodiment.

FIG. 2B is a plan view illustrating the semiconductor device according to the first exemplary embodiment.

FIG. 3A is a plan view illustrating the semiconductor device according to the first exemplary embodiment.

FIG. 3B is a plan view illustrating the semiconductor device according to the first exemplary embodiment.

FIG. 4 is a sectional view illustrating the semiconductor device according to the first exemplary embodiment.

FIG. 5A is a plan view illustrating the semiconductor device according to a second exemplary embodiment.

FIG. 5B is a plan view illustrating the semiconductor device according to the second exemplary embodiment.

FIG. 6 is a sectional view illustrating the semiconductor device according to the second exemplary embodiment.

FIG. 7A is a plan view illustrating the semiconductor device according to a third exemplary embodiment.

FIG. 7B is a plan view illustrating the semiconductor device according to the third exemplary embodiment.

FIG. 8 is a circuit diagram illustrating a pixel of a semiconductor device according to the third exemplary embodiment.

FIG. 9 is a sectional view illustrating the semiconductor device according to the third exemplary embodiment.

FIG. 10A is a plan view illustrating the semiconductor device according to a fourth exemplary embodiment.

FIG. 10B is a plan view illustrating the semiconductor device according to the fourth exemplary embodiment.

FIG. 11 is a circuit diagram illustrating a pixel of a semiconductor device according to the fourth exemplary embodiment.

FIG. 12 is a sectional view illustrating the semiconductor device according to the fourth exemplary embodiment.

FIG. 13 is a sectional view illustrating the semiconductor device according to a fifth exemplary embodiment.

FIG. 14 is a sectional view illustrating the semiconductor device according to the fifth exemplary embodiment.

FIG. 15 is a sectional view illustrating the semiconductor device according to the fifth exemplary embodiment.

FIG. 16 is a sectional view illustrating the semiconductor device according to the fifth exemplary embodiment.

FIG. 17A is a plan view illustrating the semiconductor device according to the fifth exemplary embodiment.

FIG. 17B is a plan view illustrating the semiconductor device according to the fifth exemplary embodiment.

FIG. 18A is a plan view illustrating the semiconductor device according to a sixth exemplary embodiment.

FIG. 18B is a plan view illustrating the semiconductor device according to the sixth exemplary embodiment.

FIG. 18C is a plan view illustrating the semiconductor device according to the sixth exemplary embodiment.

FIG. 18D is a plan view illustrating the semiconductor device according to the sixth exemplary embodiment.

FIG. 19 is a sectional view illustrating the semiconductor device according to the sixth exemplary embodiment.

FIG. 20A is a plan view illustrating the semiconductor device according to a seventh exemplary embodiment.

FIG. 20B is a plan view illustrating the semiconductor device according to the seventh exemplary embodiment.

FIG. 20C is a plan view illustrating the semiconductor device according to the seventh exemplary embodiment.

FIG. 20D is a plan view illustrating the semiconductor device according to the seventh exemplary embodiment.

FIG. 21 is a sectional view illustrating the semiconductor device according to the seventh exemplary embodiment.

FIG. 22A is a plan view illustrating the semiconductor device according to an eighth exemplary embodiment.

FIG. 22B is a plan view illustrating the semiconductor device according to the eighth exemplary embodiment.

FIG. 22C is a plan view illustrating the semiconductor device according to the eighth exemplary embodiment.

FIG. 22D is a plan view illustrating the semiconductor device according to the eighth exemplary embodiment.

FIG. 23 is a sectional view illustrating the semiconductor device according to the eighth exemplary embodiment.

FIG. 24 is a functional block diagram illustrating a photoelectric conversion system according to a ninth exemplary embodiment.

FIG. 25A is a functional block diagram illustrating a photoelectric conversion system according to a tenth exemplary embodiment.

FIG. 25B is a functional block diagram illustrating a photoelectric conversion system according to the tenth exemplary embodiment.

FIG. 26 is a functional block diagram illustrating a photoelectric conversion system according to an eleventh exemplary embodiment.

FIG. 27 is a functional block diagram illustrating a photoelectric conversion system according to a twelfth exemplary embodiment.

FIG. 28A is a functional block diagram illustrating a photoelectric conversion system according to a thirteenth exemplary embodiment.

FIG. 28B is a functional block diagram illustrating a photoelectric conversion system according to the thirteenth exemplary embodiment.

### DESCRIPTION OF THE EMBODIMENTS

Embodiments described below are mere implementations of the technical idea of the present invention and are not intended to limit the present invention. Sizes of components and positional relationships between components that are illustrated in the drawings may be exaggerated to clarify the description. In the following description, corresponding components are assigned the same reference numeral, and descriptions thereof are sometimes omitted.

Various exemplary embodiments of the present invention will be described in detail below with reference to the accompanying drawings. In the following description, terms indicating specific directions or positions (e.g., “top”, “bottom”, “right”, “left”, and other terms including the terms) are used as appropriate. The terms are used to facilitate understanding the exemplary embodiments with reference to the drawings, and the technical scope of the present invention is not limited to the meanings of the terms.

As used in the present specification, a plan view refers to the viewing from a direction perpendicular to a light incident surface of a semiconductor layer. A sectional view refers to a plane in a direction perpendicular to the light incident surface of the semiconductor layer. In a case where the light incident surface of the semiconductor layer is a rough surface when viewed microscopically, a plan view is defined based on the light incident surface of the semiconductor layer that is viewed macroscopically.

As used in the present specification, the term “dopant concentration” used alone refers to a net dopant concentration obtained by subtracting the portion compensated by impurities of the opposite conductivity type. In other words, a “dopant concentration” refers to a net doping concentration. A region where a p-type added dopant concentration is higher than an n-type added dopant concentration is a p-type semiconductor region. A region where an n-type added dopant concentration is higher than a p-type added dopant concentration is an n-type semiconductor region.

As used in the present specification, the phrase “to connect components A and B electrically” is not limited to a case where the components A and B are connected directly. For example, the components A and B may be connected electrically to another component C connected between the components A and B.

### First Exemplary Embodiment

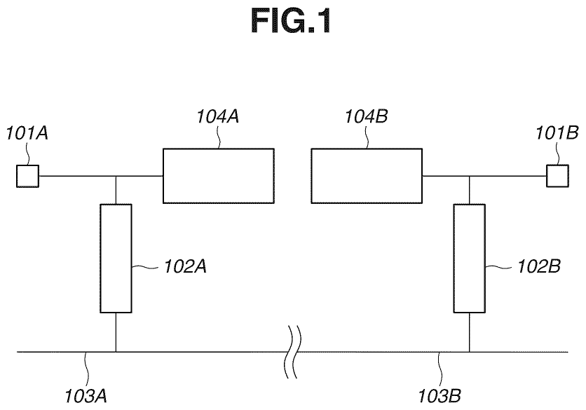

A structure of a semiconductor device according to a first exemplary embodiment of the present invention will be described below with reference to FIGS. 1 to 4.

FIG. 1 is a schematic diagram illustrating the semiconductor device according to the first exemplary embodiment. The semiconductor device according to the first exemplary embodiment includes a first pad 101A, a second pad 101B, a first protection circuit 102A, a second protection circuit 102B, a first reference potential line 103A (hereinafter, also referred to as a reference potential trace 103A), a second reference potential line 103B (hereinafter, also referred to as a reference potential trace 103B), a first internal circuit 104A, and a second internal circuit 104B.

The first pad 101A and the second pad 101B are pads for externally outputting signals generated in the semiconductor device and pads to which voltages supplied from outside to drive circuits of the semiconductor device are input. For example, a first power supply voltage is input to the first pad, and a second power supply voltage is input to the second pad.

The first protection circuit 102A is a circuit for protecting the internal circuit from external noise, such as static electricity and surge voltages, input from the first pad 101A. The second protection circuit 102B is a circuit for protecting the internal circuit from external noise input from the second pad 101B. Each protection circuit includes, for example, a diode, a Gate Grounded metal oxide semiconductor (gate grounded MOS), a resistor/capacitor (RC) Trigger metal oxide semiconductor (RC trigger MOS), or a combination thereof.

The first reference potential line 103A and the second reference potential line 103B are traces with a reference potential and are, for example, traces of power supply wiring or traces of ground wiring. The first reference potential line 103A and the second reference potential line 103B may be either separate traces or the same trace. Details of configurations of the reference potential lines will be described below.

The first internal circuit 104A and the second internal circuit 104B are disposed in the semiconductor device and each include, for example, a driver circuit for amplifying external signals.

The first protection circuit 102A is connected between the first pad 101A and the first reference potential line 103A, and the first internal circuit 104A is connected to the first pad 101A. Similarly, the second protection circuit 102B is connected between the second pad 101B and the second reference potential line 103B, and the second internal circuit 104B is connected to the second pad 101B.

In a case where external noise, such as static electricity, is applied to the first pad 101A, a current passes through the first reference potential line 103A via the protection circuit, so that the voltage to be applied to the first internal circuit 104A is clamped within a predetermined range. This makes it possible to prevent element damage or breakdown resulting from high voltage application to the first internal circuit 104A. Similarly, in a case where external noise, such as static electricity, is applied to the second pad 101B, a current passes through the second reference potential line 103B via the protection circuit, thus preventing breakdown in the second internal circuit 104B.

The first protection circuit 102A and the second protection circuit 102B may also be connected to circuit components, such as resistors or capacitors, in addition to the circuit components illustrated in FIG. 1. For example, a resistor may be connected between the first pad 101A and the first protection circuit 102A or between the first protection circuit 102A and the first internal circuit 104A to drop the voltage input from the first pad 101A, thus reducing the absolute value of the voltage to be applied to a subsequent circuit.

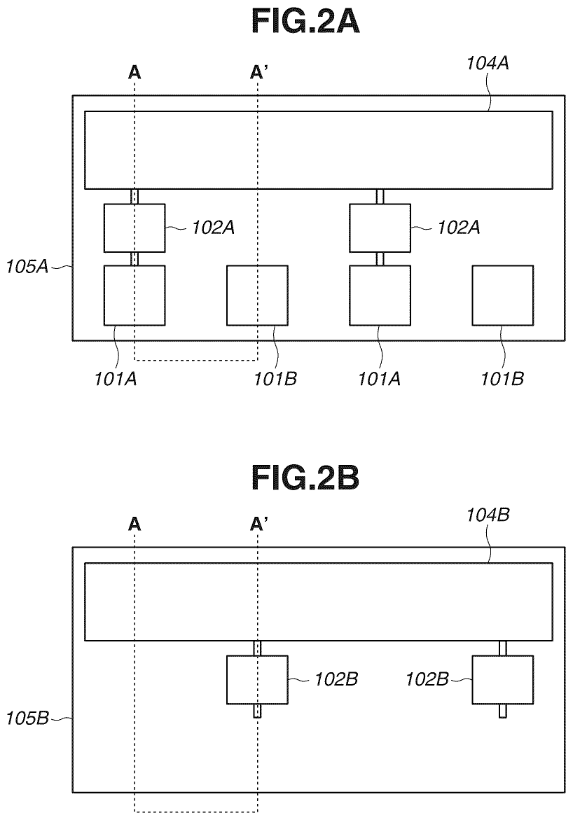

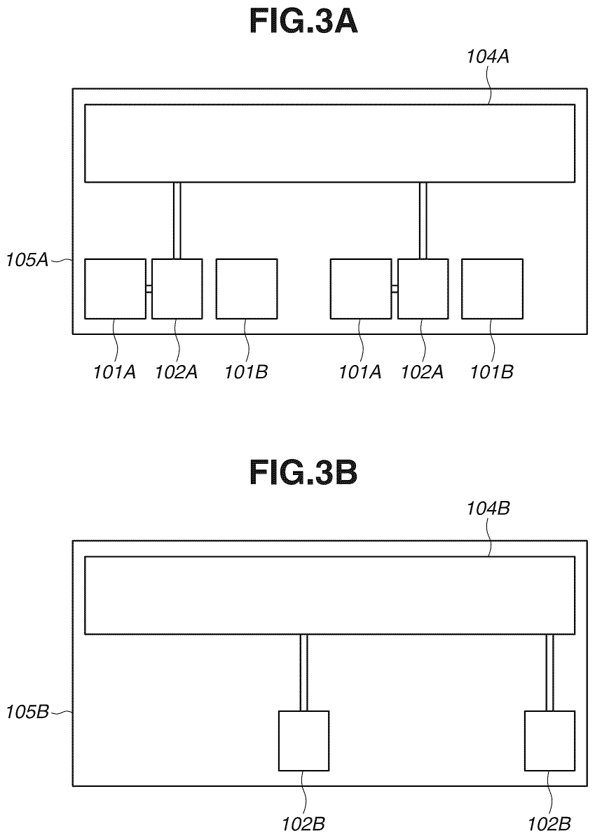

FIGS. 2A, 2B, 3A, and 3B are schematic diagrams illustrating planar layouts of the protection circuits according to the first exemplary embodiment.

The semiconductor device according to the present exemplary embodiment includes a first component 105A illustrated in FIG. 2A and a second component 105B illustrated in FIG. 2B. According to the present exemplary embodiment, the first pads 101A, the second pads 101B, the first protection circuits 102A, and the first internal circuit 104A are formed on the first component 105A, and the second protection circuits 102B and the second internal circuit 104B are formed on the second component 105B. The first component 105A and the second component 105B are stacked.

In FIG. 2A, the first protection circuits 102A on the first component 105A are disposed between the first pads 101A and the first internal circuit 104A in plan view. In FIG. 2B, the second protection circuits 102B on the second component 105B are disposed between the second pads 101B on the first component 105A and the second internal circuit 104B on the second component 105B in plan view.

The circuit layout is not limited to the foregoing layout and, for example, each of the first protection circuits 102A and the second protection circuits 102B may be disposed between one first pad 101A and one second pad 101B in plan view as illustrated in FIGS. 3A and 3B. The first protection circuits 102A on the first component 105A and the second protection circuits 102B on the second component 105B may be disposed to overlap in plan view.

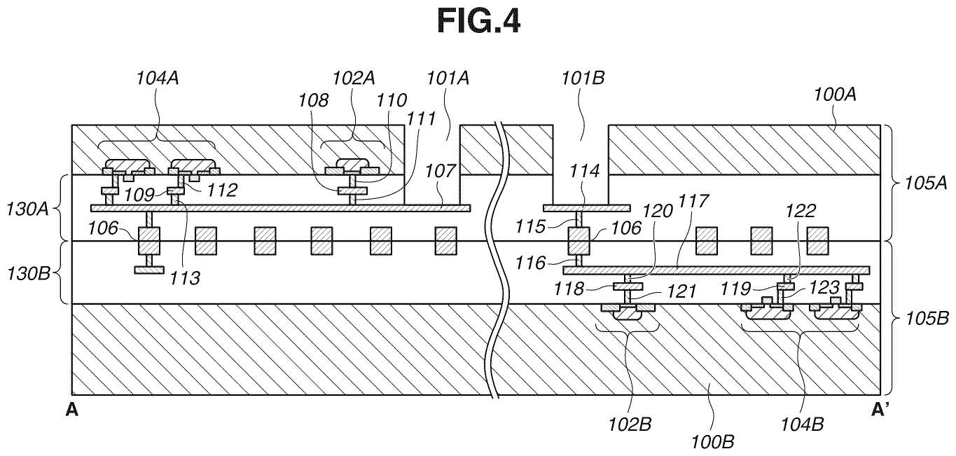

FIG. 4 is a sectional view illustrating the semiconductor device taken along a broken line AA′ illustrated in FIGS. 2A and 2B.

The semiconductor device according to the present exemplary embodiment is configured by bonding the first component 105A including a first semiconductor substrate 100A and a first wiring structure 130A and the second component 105B including a second semiconductor substrate 100B and a second wiring structure 130B together. The first wiring structure 130A includes traces 107, 108, 109, and 114 and vias 110, 111, 112, 113, and 115. The second wiring structure 130B includes traces 117, 118, and 119 and vias 116, 120, 121, 122, and 123.

The first semiconductor substrate 100A and the second semiconductor substrate 100B are, for example, silicon substrates. On each substrate, circuit elements, such as metal oxide semiconductor (MOS) transistors, transistors, capacitors, and photoelectric conversion elements, that form the internal circuits are formed.

The first component 105A and the second component 105B are electrically connected via a substrate bonding portion 106. The first wiring structure 130A included in the first component 105A and the second wiring structure 130B included in the second component 105B each include a plurality of wiring layers and a plurality of via layers. The traces 108 and 109 are disposed in a wiring layer different from a first wiring layer in which the traces 107 and 114 are disposed. The traces 118 and 119 are disposed in a third wiring layer different from a second wiring layer in which the trace 117 is disposed. Similarly, the vias 110 and 112 are disposed in the same via layer different from a via layer in which the vias 111 and 113 are disposed, and the vias 120 and 122 are disposed in the same via layer different from a via layer in which the vias 121 and 123 are disposed.

While the first component 105A and the second component 105B each include two wiring layers in FIG. 4, the number of wiring layers and the number or via layers in each wiring structure of each component are not limited thereto and may be set to any number. The traces included in the wiring layers and the vias included in the via layers are made of metal(s) such as copper, aluminum, tungsten, and/or titanium. Between the wiring layers, for example, insulation layers including silicon oxide film, silicon nitride film, and/or silicon carbide film are formed.

According to the present exemplary embodiment, the first pads 101A and the second pads 101B are disposed on the same wiring layer. Thus, the first pads 101A and the second pads 101B can be formed in the same process. The first pad 101A is formed with the trace 107 in the first component exposed by a first opening portion through which the semiconductor substrate opens from the first semiconductor substrate 100A side. Similarly, the second pad 111B is formed with the trace 114 disposed on the same wiring layer as the trace 107 exposed by a second opening portion through which the semiconductor substrate opens from the first semiconductor substrate 100A side. The pad structures are not limited thereto and, for example, an opening portion through which the semiconductor substrate opens from the first semiconductor substrate 100A side may penetrate through the first component 105A to externally expose the wiring layers included in the second wiring structure 130B of the second component 105B. An opening may be formed from the second semiconductor substrate 100B side.

The first protection circuit 102A is formed on the first semiconductor substrate 100A of the first component 105A, and the second protection circuit 102B is formed on the second semiconductor substrate 100B of the second component 105B. While the protection circuits 102A and 102B are each illustrated as a diode in FIG. 4, protection circuit elements are not limited thereto. A silicide structure (not illustrate) may be disposed on the first semiconductor substrate 100A and the second semiconductor substrate 100B.

The first protection circuit 102A is connected to the first pad 101A via the traces 107 and 108 and the vias 110 and 111. While only a terminal of the first protection circuit 102A that is connected to the first pad 101A is illustrated in FIG. 4, another terminal of the first protection circuit 102A is connected to the reference potential trace 103A (not illustrated).

The first internal circuit 104A is connected to the first pad 101A via the traces 107 and 109 and the vias 112 and 113. The first internal circuit 104A may be connected electrically to the second component 105B via the substrate bonding portion 106.

The second protection circuit 102B is connected to the second pad 101B via the traces 114, 117, and 118, the vias 115, 116, 120, and 121, and the substrate bonding portion 106. While only a terminal of the second protection circuit 102B that is connected to the second pad 101B is illustrated in FIG. 4, another terminal of the second protection circuit 102B is connected to the reference potential trace 103B (not illustrated).

The second internal circuit 104B is connected to the second pad 101B via the traces 114, 117, and 119, the vias 115, 116, 122, and 123, and the substrate bonding portion 106.

The substrate bonding portion 106 may be, for example, a bonding with a throughsilicon via (TSV) or a bonding through Cu—Cu-bonding (CCB) for bonding. Bonding by micro-bumps may also be applicable. In bonding through CCB, a portion where a first insulation layer of the first wiring structure and a second insulation layer of the second wiring structure are in contact with each other and a portion where a first metal component of the first wiring structure and a second metal component of the second wiring structure are in contact with each other are formed on a bonding surface.

A case where a plurality of stacked semiconductor substrates of a semiconductor device is each supplied with a different power supply voltage will be discussed below. In general, a greater current flows through a circuit with a higher power supply voltage, which increases risks of a decrease in wiring reliability due to electromigration and pn junction breakdown. To reduce the risks, it is effective to set great widths of traces, large spaces between the traces, and large spaces between dopant regions. Thus, in a case of stacking a plurality of substrates with different power supply voltages for driving elements on the respective substrates, an optimum design rule may be set for each substrate based on operating voltages of the elements on the respective substrates. As used in the present specification, a high voltage refers to a voltage with a potential relatively higher in absolute value than, for example, a ground potential, and a low voltage refers to a voltage with a potential relatively lower in absolute value than the ground potential.

A prior literature discusses a device configuration in which protection circuits are formed only on a substrate of a plurality of stacked semiconductor substrates. For example, in a semiconductor device including stacked substrates with different power supply voltages for driving elements on the respective substrates, protection circuits are formed on a substrate (low-voltage substrate) on which elements driven by a low voltage are disposed, in accordance with the configuration discussed in the prior publication. At this time, a protection circuit for protecting elements on a substrate (high-voltage substrate) on which elements driven by a high voltage are disposed is also formed only on the low-voltage substrate. Thus, a high voltage is applied to the low-voltage substrate and wiring disposed on the low-voltage substrate. This may cause a decrease in wiring reliability and pn junction breakdown. On the other hand, in a case where protection circuits are formed only on the high-voltage substrate, a protection circuit for protecting the elements on the low-voltage substrate is to be designed based on a design rule for the high-voltage substrate. In this case, widths of traces, spaces between the traces, and spaces between dopant regions increase, and the circuit area increases.

Thus, in the semiconductor device according to the present invention, a protection circuit to which a high voltage is applied is formed on a substrate on which elements to be driven by a high voltage are disposed, and a protection circuit to which a low voltage is applied is formed on a substrate on which elements to be driven by a low voltage are disposed. At this time, the protection circuit to which a high voltage is applied is formed based on a process rule of the high-voltage substrate side, and the protection circuit on the low-voltage substrate is formed based on a process rule of the low-voltage substrate side. Thus, for example, a gate oxide film of the protection circuit to which a high voltage is applied is thicker than a gate oxide film of the protection circuit to which a low voltage is applied, in order to improve dielectric strength. A contact to a source and a drain and a plug connected to a gate are thicker in the protection circuit disposed on the high-voltage substrate than in the protection circuit disposed on the low-voltage substrate. Further, the protection circuit disposed on the high-voltage substrate is greater in size of insulation separation around the protection circuit than the protection circuit disposed on the low-voltage substrate. This enables both prevention of a decrease in wiring reliability and pn junction breakdown and optimalization of the seizes of the circuits.

The idea of the present exemplary embodiment is applicable not only to semiconductor devices with a stacking structure including two semiconductor substrates but also, for example, to semiconductor devices with a stacking structure including three or more semiconductor substrates.

### Second Exemplary Embodiment

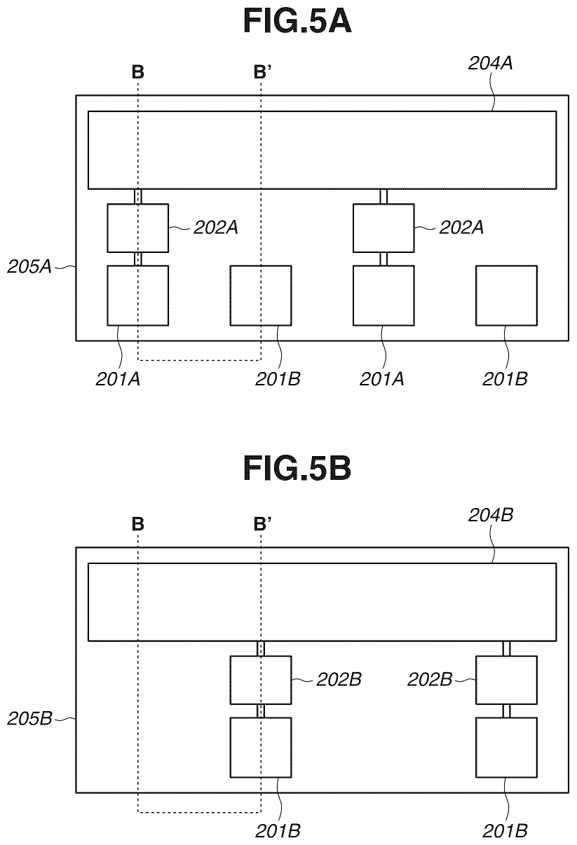

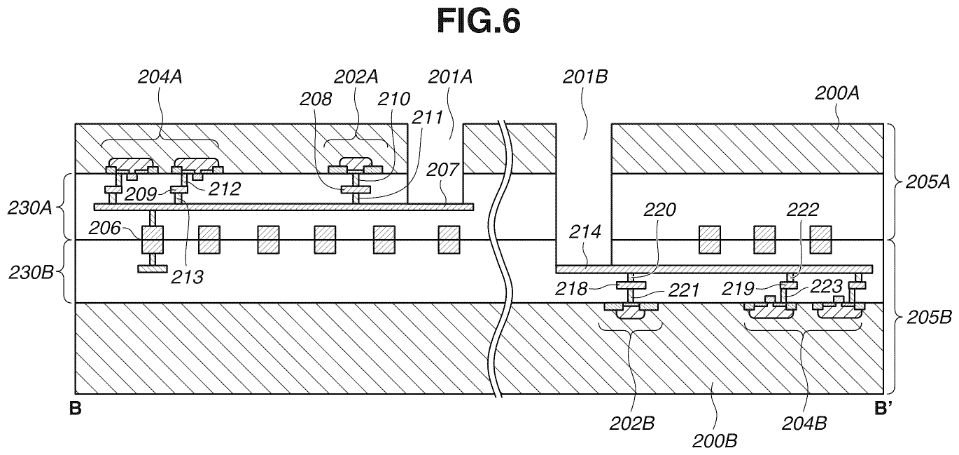

A structure of a semiconductor device according to a second exemplary embodiment of the present invention will be described below with reference to FIGS. 5A, 5B, and 6.

FIGS. 5A and 5B are planar layout diagrams illustrating protection circuits according to the second exemplary embodiment. The semiconductor device according to the present exemplary embodiment includes a first component 205A illustrated in FIG. 5A and a second component 205B illustrated in FIG. 5B. According to the present exemplary embodiment, first pads 201A, first protection circuits 202A, and a first internal circuit 204A are formed on the first component 205A. Further, second protection circuits 202B and a second internal circuit 204B are formed on the second component 205B. In FIGS. 5A and 5B, the first protection circuits 202A are disposed between the first pads 201A and the first internal circuit 204A in plan view, and the second protection circuits 202B are disposed between second pads 201B and the second internal circuit 204B in plan view. The circuit layout is not limited thereto, and each protection circuit may be disposed between one first pad 201A and one second pad 201B as in FIGS. 3A and 3B. The first protection circuits 202A and the second protection circuits 202B may be disposed to overlap in plan view.

FIG. 6 is a sectional view illustrating the semiconductor device taken along a broken line BB′ illustrated in FIGS. 5A and 5B. The semiconductor device according to the present exemplary embodiment includes the first component 205A and the second component 205B that are bonded together. The first component 205A includes a first semiconductor substrate 200A and a first wiring structure 230A. The second component 205B includes a second semiconductor substrate 200B and a second wiring structure 230B. The semiconductor device according to the present exemplary embodiment differs from the first exemplary embodiment in that a wiring layer in which wiring constituting the first pad 201A is disposed differs from a wiring layer in which wiring constituting the second pad 201B is disposed.

According to the present exemplary embodiment, the first pad 201A is configured such that the semiconductor substrate opens from the first semiconductor substrate 200A side with a trace 207 in the first wiring structure 230A of the first component 205A exposed. In contrast, the second pad 201B is configured such that an opening through which the semiconductor substrate opens from the second semiconductor substrate 200B side penetrates through the first component 205A with a trace 217 included in the second wiring structure 230B of the second component 205B exposed.

According to the first exemplary embodiment, the first pad 101A and the second pad 101B are wiring included in the same wiring layer, so that the first exemplary embodiment is advantageous in that the plurality of pads is formable in the same process. However, the second pad 101B and the second internal circuit 104B are connected via the traces 114, 117, and 119, the vias 115, 116, 122, and 123, and the substrate bonding portion 106, which increases a distance between the pad and the internal circuit. This may cause a power supply voltage drop or signal delay due to an increased wiring resistance. In contrast to this, in the semiconductor device structure according to the second exemplary embodiment, the second pad 201B is the wiring included in the wiring layer in the second wiring structure 230B, so that a wiring resistance from the pad to the internal circuit is reduced and a power supply voltage drop and signal delay are prevented.

### Third Exemplary Embodiment

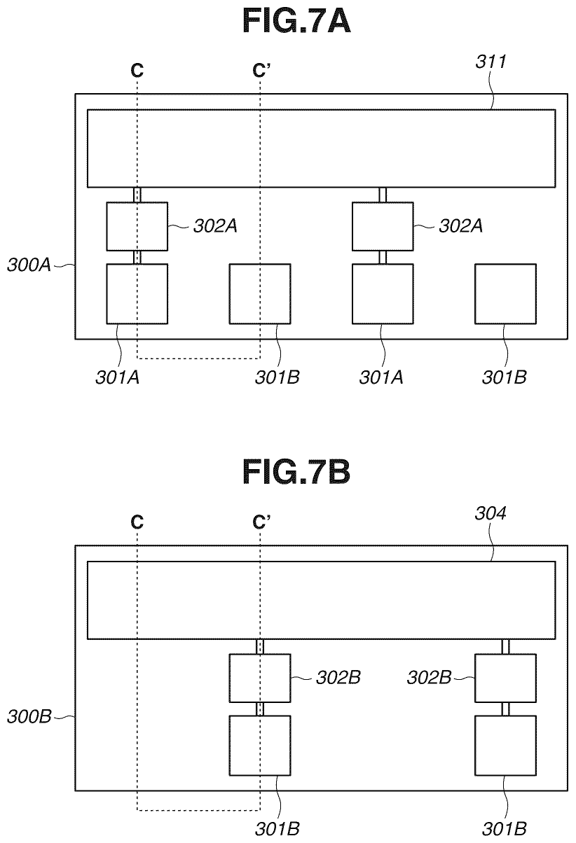

A structure of a semiconductor device according to a third exemplary embodiment of the present invention will be described below with reference to FIGS. 7A to 9. The semiconductor device according to the third exemplary embodiment includes a complementary MOS (CMOS) sensor as part of an internal circuit. FIGS. 7A and 7B are schematic diagrams illustrating planar layouts of protection circuits according to the third exemplary embodiment.

The semiconductor device according to the present exemplary embodiment includes a first component 305A illustrated in FIG. 7A and a second component 305B illustrated in FIG. 7B that are bonded together. According to the present exemplary embodiment, first pads 301A, first protection circuits 302A, and a CMOS sensor 311 are formed on the first component 305A. Further, second protection circuits 302B and an internal circuit 304 are formed on the second component 305B. The internal circuit 304 is, for example, a processing circuit that processes signal charge generated by the CMOS sensor 311.

In FIGS. 7A and 7B, the first protection circuits 302A are disposed between the first pads 301A and the CMOS sensor 311, and the second protection circuits 302B are disposed between second pads 301B and the internal circuit 304. The circuit layout is not limited thereto, and each protection circuit may be disposed between one first pad 301A and one second pad 301B as in FIGS. 3A and 3B. The first protection circuits 302A and the second protection circuits 302B may be disposed to overlap in plan view.

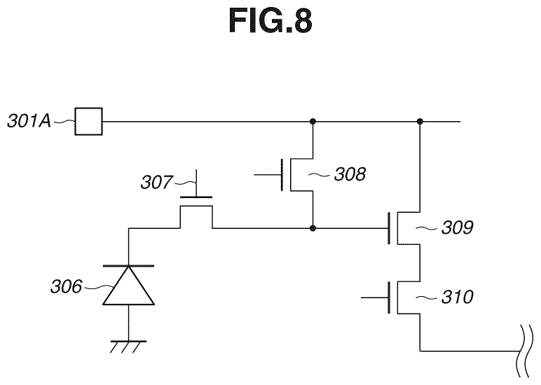

FIG. 8 illustrates an example of a pixel 315 constituting the CMOS sensor 311 illustrated in FIGS. 7A and 7B. The CMOS sensor 311 includes the pixels 315 arranged in an array.

The pixel 315 includes a photodiode 306, a transfer transistor 307, a reset transistor 308, an amplification transistor 309, and a row selection transistor 310. An output terminal of the photodiode 306 is connected to either a source or a drain of the transfer transistor 307, and the other is connected to either a source or a drain of the reset transistor 308 and to a gate of the amplification transistor 309. Either a source or a drain of the amplification transistor is connected to either a source or a drain of the row selection transistor 310. The reset transistor 308 and the amplification transistor 309 are connected to a common power supply, and this power supply is supplied from the first pad 301A. The row selection transistor 310 is connected to a vertical output line and transmits signals obtained in the photodiode 306 to an internal circuit including an analog to digital (AD) conversion circuit (not illustrated) and/or a horizontal output circuit (not illustrated).

The pixels 315 included in the CMOS sensor 311 are arranged in an array in a first semiconductor substrate 300A, and signals obtained by a sensor selected by the row selection transistor 310 are transmitted to the internal circuit 304 in a second semiconductor substrate 300B. All of the components 306 to 310 of the CMOS sensor 311 may be formed on the semiconductor substrate 300A, or some of the components 306 to 310 may be formed on the semiconductor substrate 300B.

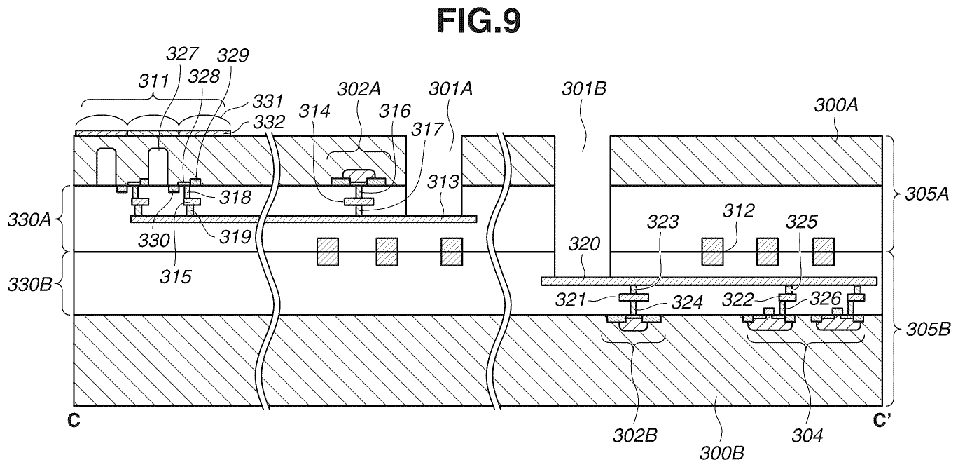

FIG. 9 is a sectional view illustrating the semiconductor device taken along a broken line CC′ illustrated in FIGS. 7A and 7B. The semiconductor device according to the present exemplary embodiment includes the first component 305A and the second component 305B that are bonded together. The first component 305A includes the first semiconductor substrate 300A and a first wiring structure 330A. The second component 305B includes the second semiconductor substrate 300B and a second wiring structure 330B. Here, the first pad 301A is configured such that the semiconductor substrate opens from the first semiconductor substrate 300A side with a trace 313 in the first wiring structure 330A of the first component 305A exposed. In contrast, the second pad 301B has an opening portion that penetrates through the first component 305A from the first semiconductor substrate 300A side, with a trace 320 of the second wiring structure 330B in the second component 305B exposed. The pad configuration is not limited thereto and, for example, the first pad 301A and the second pad 301B may be disposed in the same wiring layer as in the first exemplary embodiment.

According to the present exemplary embodiment, the CMOS sensor 311 is formed as an example of the internal circuits 104A and 204A in FIGS. 4 and 6. N-type semiconductor regions 327 and 328 and an element isolation structure 329 are disposed in the first semiconductor substrate 300A. The n-type semiconductor region 327 constitutes the photodiode 306, and the n-type semiconductor region 328 is the drain of the transfer transistor 307. The transfer transistor 307 includes the n-type semiconductor regions 327 and 328 and a gate electrode 330, and charge generated and accumulated in the n-type semiconductor region 327 is transferred to the n-type semiconductor region 328 by the gate electrode 330. On the back side of the CMOS sensor 311, a color filter layer 332 including color filters corresponding to respective pixels 315 and a microlens layer 331 including microlenses are disposed. While FIG. 9 illustrates a so-called back-irradiated CMOS sensor into which light enters from the microlens layer 331, the configuration of the CMOS sensor 311 is not limited to the illustrated configuration.

Here, a circuit operating voltage may be varied between the first semiconductor substrate 300A in which the CMOS sensor 311 is formed and the second semiconductor substrate 300B in which the internal circuit is formed. For example, a high voltage may be applied to the first semiconductor substrate 300A to increase the sensitivity of the CMOS sensor 311 while a low voltage may be applied to the second semiconductor substrate 300B for high-speed operation of the internal circuit.

According to the present invention, the first protection circuit 302A connected to the first pad 301A to be supplied with a power supply voltage for operation of the CMOS sensor 311 is formed on the first semiconductor substrate 300A. The second protection circuit 302B connected to the second pad 301B to be supplied with a voltage for driving the internal circuit is formed in the second semiconductor substrate 300B. This configuration enables both prevention of a decrease in wiring reliability and pn junction breakdown due to a high-voltage power supply for sensor operation and optimalization of the seizes of the circuits.

### Fourth Exemplary Embodiment

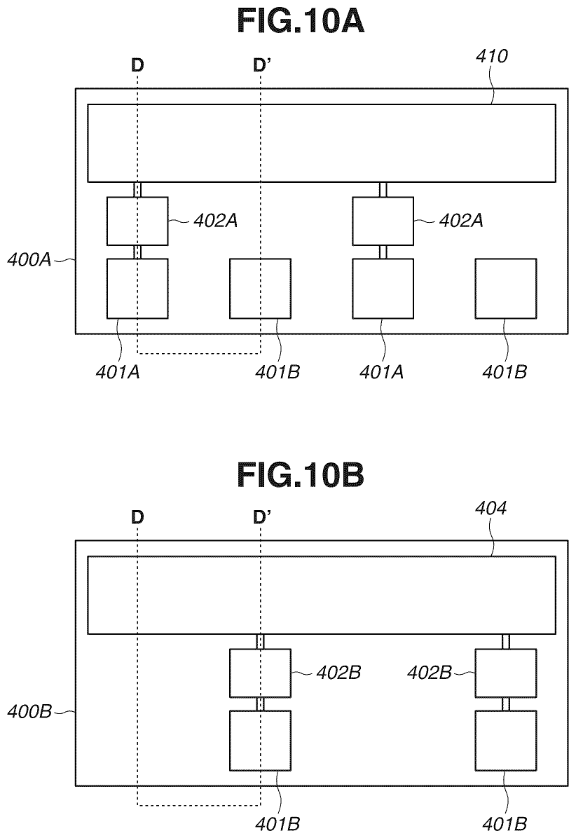

A structure of a semiconductor device according to a fourth exemplary embodiment of the present invention will be described below with reference to FIGS. 10A to 12. The present exemplary embodiment features a Single Photon Avalanche Diode (SPAD) 410 that is formed in place of the CMOS sensor 311 described in conjunction with FIGS. 7A and 7B.

In the following description, an anode of an avalanche photodiode (APD) is fixed at a constant potential, and signals are extracted from the cathode side. Thus, a semiconductor region of a first conductivity type where a large number of carriers have the same polarity as the signal charge is an N-type semiconductor region, and a semiconductor region of a second conductivity type where a large number of carriers have the opposite polarity to the signal charge is a P-type semiconductor region. The present invention is also established in a case where the cathode of the APD is fixed at a constant potential and signals are extracted from the anode side. In such a case, a semiconductor region of a first conductivity type where a large number of carriers have the same polarity as the signal charge is a P-type semiconductor region, and a semiconductor region of a second conductivity type where a large number of carriers have the opposite polarity to the signal charge is an N-type semiconductor region. While a case where one node of the APD is fixed at a constant potential will be described below, both potentials of the nodes may be varied.

FIGS. 10A and 10B are planar layout images illustrating protection circuits according to the fourth exemplary embodiment. The semiconductor device according to the present exemplary embodiment includes a first component 405A illustrated in FIG. 10A and a second component 405B illustrated in FIG. 10B bonded together. The first component 405A includes a first semiconductor substrate 400A and a first wiring structure 430A, and the second component 405B includes a second semiconductor substrate 400B and a second wiring structure 430B.

According to the present exemplary embodiment, first pads 401A, first protection circuits 402A, and a SPAD sensor 410 are formed on the first component 405A. Further, second protection circuits 402B and an internal circuit 404 are formed on the second component 405B. In FIGS. 10A and 10B, the first protection circuits 402A are disposed between the first pads 401A and the SPAD sensor 410, and the second protection circuits 402B are disposed between second pads 401B and the internal circuit 404. The circuit layout is not limited to this layout, and each protection circuit may be disposed between one first pad 401A and one second pad 401B as in FIGS. 3A and 3B. The first protection circuits 402A and the second protection circuits 402B may be disposed to overlap in plan view.

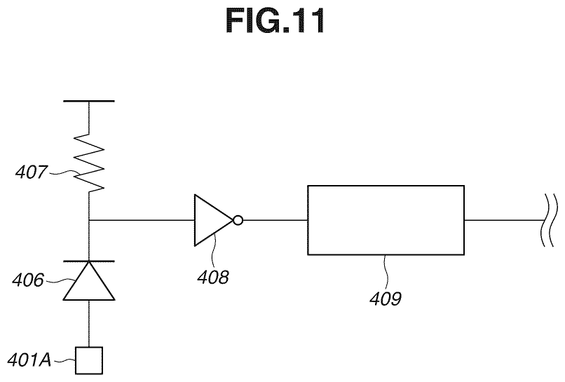

FIG. 11 illustrates an example of an overview of the SPAD sensor 410 illustrated in FIGS. 10A and 10B. The SPAD sensor 410 is an avalanche photodiode and includes a photodiode 406, a quenching element 407, an inverter circuit 408, and a counter circuit 409. A high-voltage power supply with negative polarity is supplied to the first pad 401A, and electrons generated through photoelectric conversion in the photodiode 406 undergo avalanche multiplication. The amplified electrons are shaped into pulses through the inverter circuit 408, and the pulses are transmitted to the counter circuit 409. One counter circuit 409 may be connected to one photodiode 406, or one counter circuit 409 may be connected to the plurality of photodiodes 406. All of the circuit components 406 to 409 may be formed on the first semiconductor substrate 400A, or some of the components may be formed on the second semiconductor substrate 400B. The quenching element 407 may be a resistor element or a transistor. The quenching element may have a variable resistance value or may be, for example, an element with a resistance value that changes periodically.

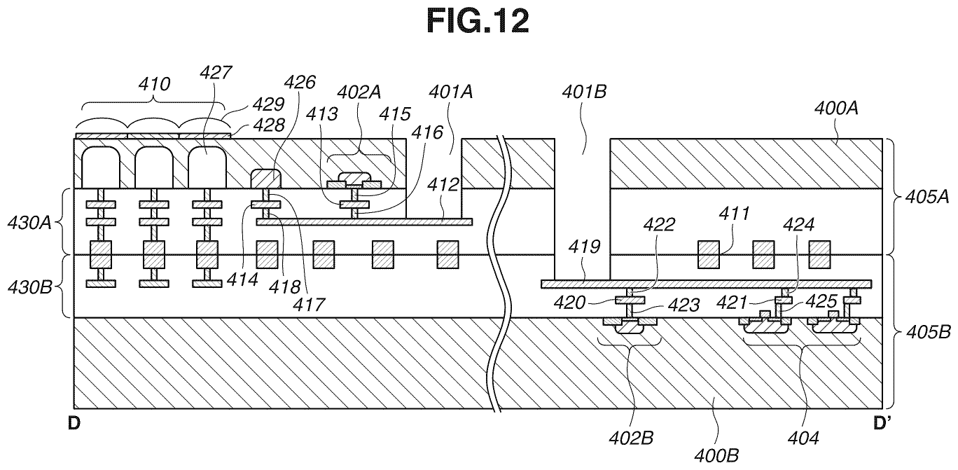

FIG. 12 is a sectional view illustrating the semiconductor device taken along a broken line DD′ illustrated in FIGS. 10A and 10B. The semiconductor device according to the present exemplary embodiment includes the first component 405A the second component 405B that are bonded together. The first component 405A includes the first semiconductor substrate 400A and the first wiring structure 430A. The second component 405B includes the second semiconductor substrate 400B and the second wiring structure 430B. The first pad 401A is formed by opening the semiconductor substrate from the first semiconductor substrate 400A side to expose a trace 412 of the first wiring structure 430A in a first component 405A. Further, the second pad 401B has an opening portion penetrating through the first component 405A to expose a trace 419 of the second wiring structure 430B in the second component 405B. The first pad 401A and the second pad 401B may be disposed in the same wiring layer as in the first exemplary embodiment.

According to the present exemplary embodiment, the SPAD sensor 410 is formed as an example of the internal circuits 104A and 204A in FIGS. 4 and 6 or in place of the CMOS sensor in FIG. 9. In FIG. 12, only the photodiode 406 illustrated in FIG. 11 and the first protection circuit 402A are formed on the first semiconductor substrate 400A. The element layout is not limited to this layout, and the circuit components 407 to 409 may be formed on the first semiconductor substrate 400A. On the light incident surface side of the SPAD sensor 410, a color filter layer 428 including a plurality of color filters and a microlens layer 429 including a plurality of microlenses are disposed. While a so-called back-irradiated SPAD sensor is illustrated in FIG. 12, the described SPAD sensor configuration according to the present exemplary embodiment is not a limitation but a mere example.

In the SPAD sensor 410, a high voltage with negative polarity is applied to the photodiode 406, and charge obtained through photoelectric conversion undergoes avalanche multiplication. Thus, a high voltage is applied to the first semiconductor substrate 400A. In the configuration according to the present invention, the first protection circuit 402A to be connected to the first pad 401A to which a high voltage with negative polarity for avalanche multiplication is applied is formed on the first semiconductor substrate 400A. Meanwhile, the second protection circuit 402B to be connected to the second pad 401B to which a lower voltage is applied than a voltage to be applied to the first pad 401A is formed on the second semiconductor substrate 400B. This configuration enables both prevention of a decrease in wiring reliability and pn junction breakdown and optimalization of the seizes of the circuits.

### Fifth Exemplary Embodiment

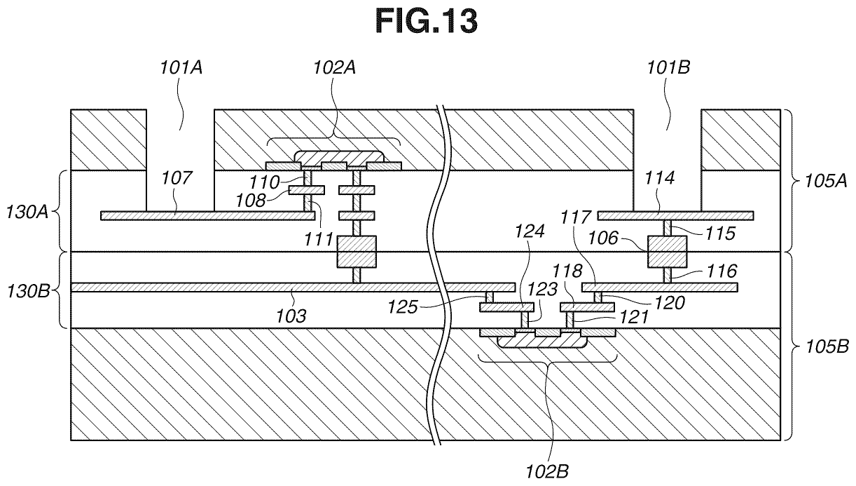

A structure of a semiconductor device according to a fifth exemplary embodiment of the present invention will be described below with reference to FIGS. 13 to 17B.

According to the first to fourth exemplary embodiments, a protection element is disposed on each of low- and high-voltage substrates. One terminal of a protection circuit on each substrate is connected to an internal circuit of the corresponding substrate, and another terminal is connected to a reference potential line. In this case, disposing the reference potential line on each substrate may lead to a decrease in area efficiency. Thus, according to the present exemplary embodiment, a reference potential line to be connected to each of a protection circuit disposed on a low-voltage substrate and a protection circuit disposed on a high-voltage substrate is formed in one of the stacked substrates, which is a feature of the present exemplary embodiment.

Variations of reference potential line layouts will be described below with reference to FIGS. 13 to 17B.

FIG. 13 is a sectional view illustrating a semiconductor device according to the first exemplary embodiment. The first pad 101A for the high-voltage substrate and the second pad 101B for the low-voltage substrate are disposed in a common wiring layer in the high-voltage substrate. One terminal of the first protection circuit 102A of the high-voltage substrate and one terminal of the second protection circuit 102B of the low-voltage substrate are connected to a common reference potential line 103 disposed in the low-voltage substrate. Disposing the reference trace 103 in the low-voltage substrate, which has a high degree of wiring layout freedom, makes it possible to enhance area efficiency.

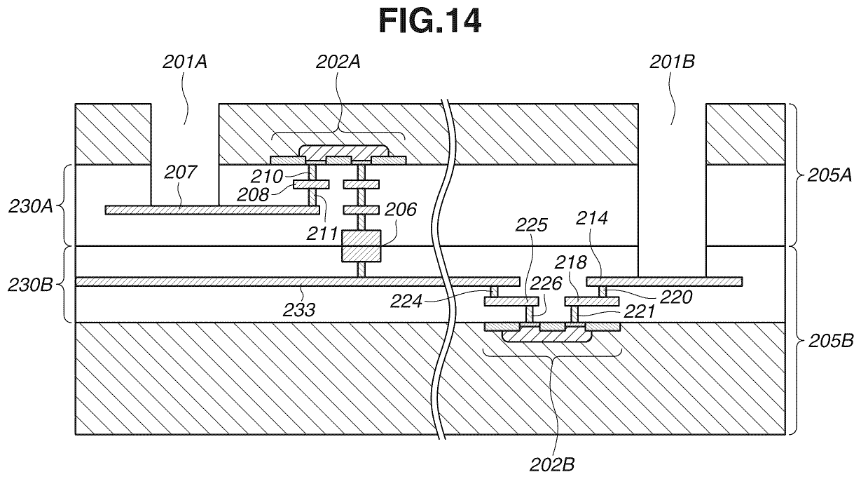

FIG. 14 is a sectional view illustrating a semiconductor device according to the second exemplary embodiment. The first pad 201A for the high-voltage substrate is disposed in the wiring layer in the high-voltage substrate, and the second pad 201B for the low-voltage substrate is disposed in the wiring layer in the low-voltage substrate. One terminal of the first protection circuit 202A in the high-voltage substrate and one terminal of the second protection circuit 202B in the low-voltage substrate are connected to a common reference potential line 233 disposed in the low-voltage substrate. In this configuration, the first pad 201A and the second pad 201B are disposed on the different substrates, thus reducing a wiring resistance from the respective pads to the corresponding internal circuit. This prevents a power supply voltage drop and signal delay. Furthermore, disposing the reference trace 103 in the low-voltage substrate, which has a high degree of wiring layout freedom, makes it possible to enhance area efficiency.

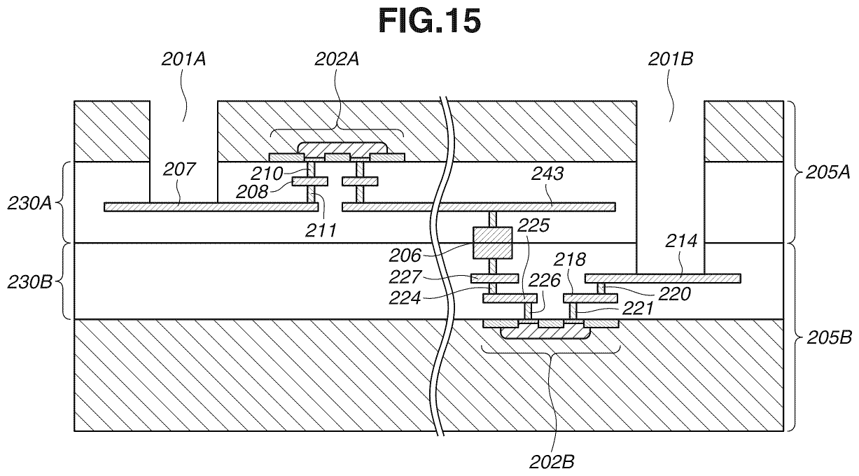

FIG. 15 is a sectional view illustrating a semiconductor device according to the second exemplary embodiment. As in FIG. 14, the first pad 201A for the high-voltage substrate is disposed in the wiring layer in the high-voltage substrate, and the second pad 201B for the low-voltage substrate is disposed in the wiring layer in the low-voltage substrate. One terminal of the first protection circuit 202A in the high-voltage substrate and one terminal of the second protection circuit 202B in the low-voltage substrate are connected to a common reference potential line 243 disposed in the high-voltage substrate, which is a difference from FIG. 14. Disposing the reference potential line 243 in the high-voltage substrate makes it possible to reduce the possibility that potential changes in the first pad 201A and the first internal circuit 204A connected to the reference potential line 243 spread to the low-voltage substrate.

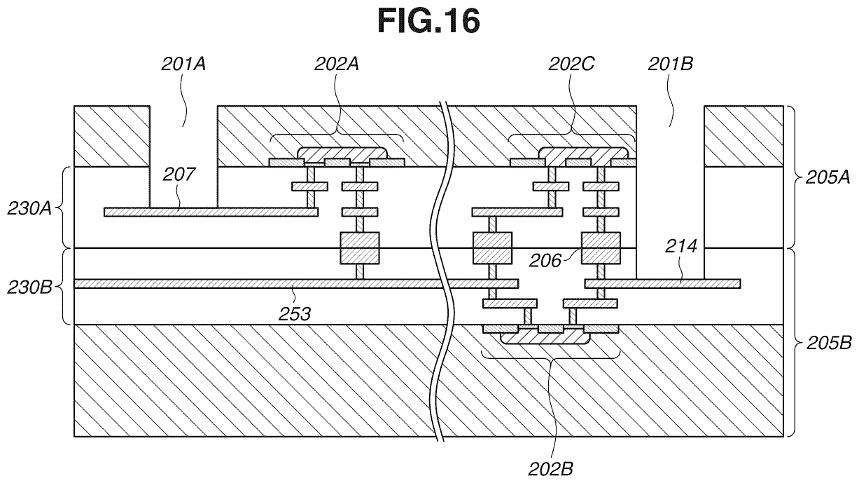

FIG. 16 is a sectional view illustrating a semiconductor device according to the second exemplary embodiment. As in FIGS. 14 and 15, the first pad 201A for the high-voltage substrate is disposed in the wiring layer in the high-voltage substrate, and the second pad 201B for the low-voltage substrate is disposed in the wiring layer in the low-voltage substrate. One terminal of the first protection circuit 202A in the high-voltage substrate and one terminal of the second protection circuit 202B in the low-voltage substrate are connected to a common reference potential line 253 disposed in the low-voltage substrate. Furthermore, a third protection circuit 202C connected to the second pad 201B in the low-voltage substrate and disposed in the high-voltage substrate is included.

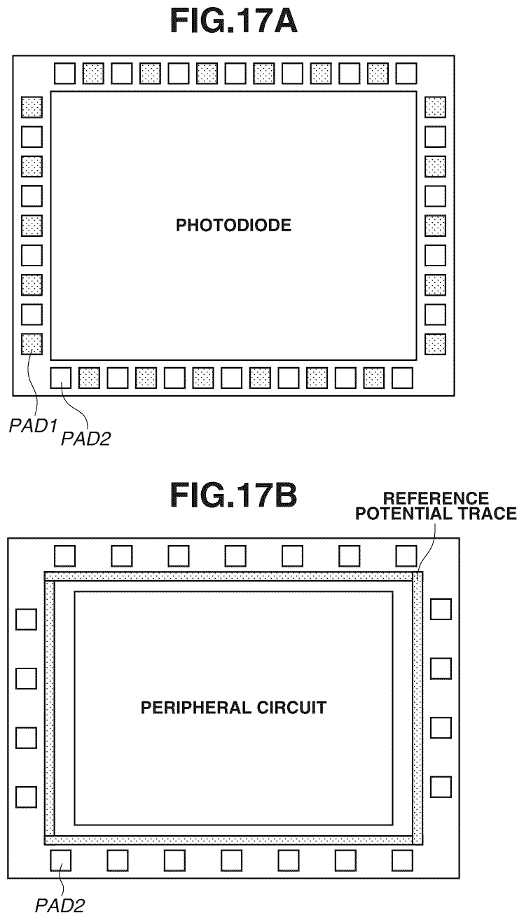

FIGS. 17A and 17B are plan views illustrating a semiconductor device according to the present exemplary embodiment. These illustrations corresponds to a case where the reference potential line illustrated in FIG. 14 or 16 is disposed in the low-voltage substrate.

FIG. 17A illustrates the high-voltage substrate on which, for example, pixels, such as the CMOS sensor 311 or the SPAD 410, are disposed, and FIG. 17B illustrates the low-voltage substrate on which, for example, a peripheral circuit is disposed. Pads (PAD1) for the high-voltage substrate and pads (PAD2) for the low-voltage substrate are alternately disposed around a pixel region of the high-voltage substrate. On the low-voltage substrate, a reference potential trace is formed to surround a peripheral region, and pads for the low-voltage substrate are disposed around the reference potential trace.

As described above, the high-voltage substrate and the low-voltage substrate are connected via the wiring structure including the plurality of wiring layers. A shared potential wiring is formed using at least three wiring layers, and a trace width of, for example, about 50 m to about 100 m is ensured. Ensuring a gage of the trace width makes it possible to connect a plurality of vias to the common potential trace.

### Sixth Exemplary Embodiment

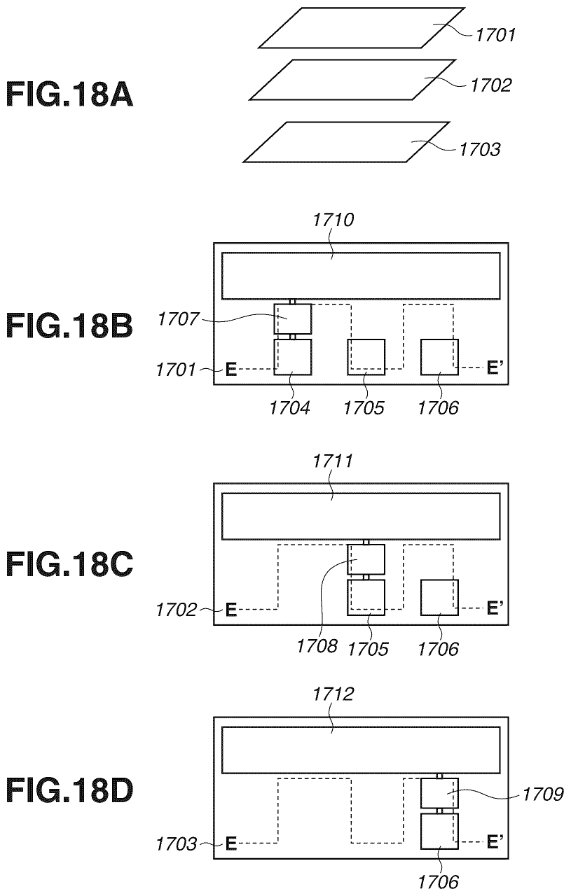

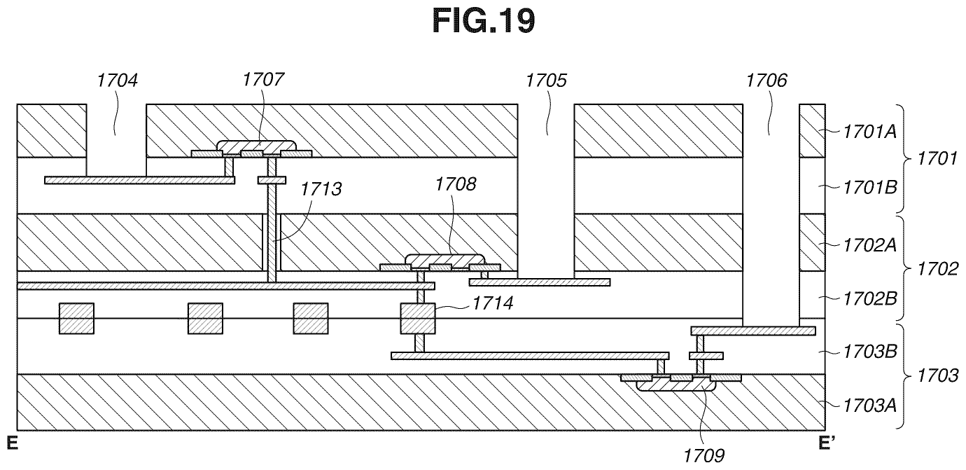

A structure of a semiconductor device according to a sixth exemplary embodiment of the present invention will be described below with reference to FIGS. 18A to 18D and 19. Descriptions have been provided of the method of arranging a protection circuit on a semiconductor device that includes two components in the first to fifth exemplary embodiments. The sixth exemplary embodiment features inclusion of three components (first component 1701, second component 1702, third component 1703). Descriptions of common elements to those according to the first to fifth exemplary embodiments are omitted, and feature portions of the sixth exemplary embodiment will be mainly described below.

FIGS. 18A to 18D are schematic diagrams including plan views each illustrating the semiconductor device according to the sixth exemplary embodiment. The semiconductor device according to the present exemplary embodiment includes three components, namely the first component 1701, the second component 1702, and the third component 1703, as illustrated in FIG. 18A.

FIG. 18B illustrates a layout of elements of the first component 1701. A first pad 1704, a first protection circuit 1707, and a first internal circuit 1710 are disposed on the first component 1701. Furthermore, the first component 1701 has an opening portion penetrating through the first component 1701 toward a second pad 1705 disposed on the second component 1702 and a third pad 1706 disposed on the third component 1703.

FIG. 18C illustrates a layout of elements of the second component 1702. The second pad 1705, a second protection circuit 1708, and a second internal circuit 1711 are disposed on the second component 1702. Furthermore, the second component 1702 has an opening portion penetrating through the second component 1702 toward the third pad 1706 disposed on the third component 1703.

FIG. 18D illustrates a layout of elements of the third component 1703. The third pad 1706, a third protection circuit 1709, and a third internal circuit 1712 are disposed on the third component 1703.

The first pad 1704, the second pad 1705, and the third pad 1706 externally output signals generated in the semiconductor device and are applied with externally-supplied voltages for driving circuits of the semiconductor device. For example, a first power supply voltage is input to the first pad 1704, a second power supply voltage is input to the second pad 1705, and a third power supply voltage is input to the third pad 1706. Further, the first protection circuit 1707 is connected to the first pad 1704, the second protection circuit 1708 is connected to the second pad 1705, and the third protection circuit 1709 is connected to the third pad 1706.

The first protection circuit 1707 is disposed in a region between the first pad 1704 and the first internal circuit 1710 in plan view, and the first pad 1704 and the first internal circuit 1710 are connected to each other via the first protection circuit 1707. The second protection circuit 1708 is disposed in a region between the second pad 1705 and the second internal circuit 1711, and the second pad 1705 and the second internal circuit 1711 are connected to each other via the second protection circuit 1708. The third protection circuit 1709 is disposed in a region between the third pad 1706 and the third internal circuit 1712, and the third pad 1706 and the third internal circuit 1712 are connected to each other via the third protection circuit 1709.

Positions of the protection circuits are not limited to regions between the pads and the internal circuits, and the protection circuits may be disposed, for example, between the pads. The protection circuits may be disposed in regions that overlap in plan view.

FIG. 19 is a sectional view illustrating the semiconductor device taken along a broken line EE′ illustrated in FIGS. 18B to 18D.

The first component 1701 includes a first semiconductor substrate 1701A and a first wiring layer 1701B. The second component 1702 includes a second semiconductor substrate 1702A and a second wiring layer 1702B. The third component 1703 includes a third semiconductor substrate 1703A and a third wiring layer 1703B.

According to the present exemplary embodiment, the first wiring layer 1701B and the second semiconductor substrate 1702A are bonded together, and the second wiring layer 1702B and the third wiring layer 1703B are bonded together. Thus, the semiconductor device according to the sixth exemplary embodiment is formed by stacking the first semiconductor substrate 1701A, the first wiring layer 1701B, the second semiconductor substrate 1702A, the second wiring layer 1702B, the third wiring layer 1703B, and the third semiconductor substrate 1703A in this order from the top of FIG. 19. Here, the first wiring layer 1701B and the second wiring layer 1702B may electrically be connected to each other via, for example, a contact portion 1713 that penetrates through the substrate, and the second wiring layer 1702B and the third wiring layer 1703B may electrically be connected to each other via a substrate bonding portion 1714. The contact portion 1713 is mainly composed of metal, such as tungsten or copper. The substrate bonding portion 1714 typically contains mainly copper and further contains a barrier metal (titanium, nickel) for preventing copper spread.

The first protection circuit 1707 is disposed on the first semiconductor substrate 1701A, and the second protection circuit 1708 is disposed on the second semiconductor substrate 1702A. Further, the third protection circuit 1709 is disposed on the third semiconductor substrate 1703A. In other words, each protection element is disposed on a semiconductor substrate near a wiring layer with a pad to which a voltage corresponding to the substrate is applied, and the wiring layer including the pads, and the semiconductor substrate including the protection element form one component. Disposing a reference potential trace (not illustrated) in one of the substrates makes it possible to reduce the wiring area.

A case where the SPAD sensor according to the fourth exemplary embodiment is applied to the semiconductor device according to the present exemplary embodiment will now be considered. A possible configuration in this case may be one in which, for example, the avalanche photodiode 410 illustrated in FIG. 11 is disposed as the first internal circuit 1710, the quenching element 407 and/or the inverter circuit 408 are disposed as the second internal circuit 1711, and the counter circuit 409 and other peripheral circuits are disposed as the third internal circuit 1712. The structure in which three components are stacked makes it possible to increase sizes of the quenching element 407 and/or the inverter circuit 408 of the SPAD as compared to the semiconductor device in which two components are stacked, so that effects of reducing variations in element manufacturing and reducing noise can be expected.

In the case of the foregoing configuration, a high-voltage power supply of negative polarity for subjecting electrons generated through photoelectric conversion to avalanche multiplication is supplied to the first semiconductor substrate 1701A. Meanwhile, it is common to operate the elements disposed on the second semiconductor substrate 1702A at a higher voltage than a voltage at which the elements disposed on the third semiconductor substrate 1703A are operated. Thus, the absolute values of the voltages to be supplied to the substrates have the following relationship:

|first power supply voltage|>>|second power supply voltage|>|third power supply voltage|.

The magnitude relationship between the voltages to be supplied to the substrates can also be expressed as follows:

|first power supply voltage−second power supply voltage|>|second power supply voltage−third power supply voltage|, and

|first power supply voltage−third power supply voltage|>|second power supply voltage−third power supply voltage|.

Thus, according to the present exemplary embodiment, even in a case where different power supply voltages are supplied to three components, protection circuits are designed based on an optimum design rule set for each component. This enables both prevention of a decrease in wiring reliability and pn junction breakdown and optimalization of the seizes of the circuits.

The foregoing configuration is a mere example, and types of elements disposed on the substrates and relationships between the supplied voltages are not limited to those described above. For example, an element other than the avalanche photodiode may be disposed on the first component 1701, or the quenching element 407 and/or part of the inverter circuit 408 may be disposed on the third component 1703.

### Seventh Exemplary Embodiment

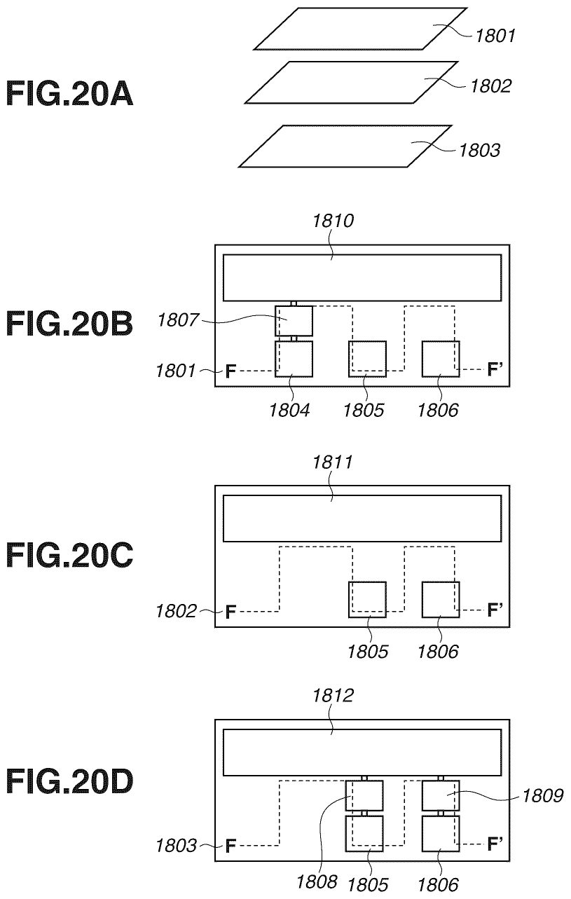

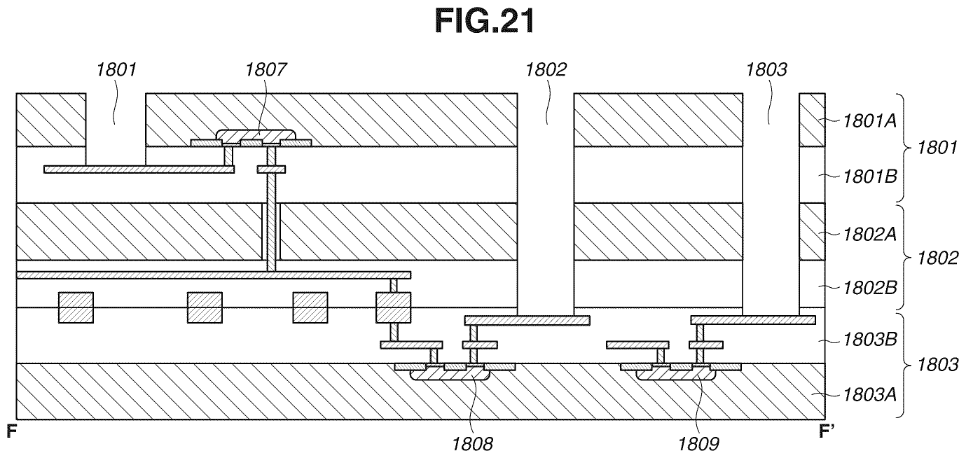

A structure of a semiconductor device according to a seventh exemplary embodiment of the present invention will be described below with reference to FIGS. 20A to 20D and 21. The semiconductor device according to the seventh exemplary embodiment includes three substrates as in the sixth exemplary embodiment, and components of the semiconductor device according to the seventh exemplary embodiment are bonded together through a method similar to that according to the sixth exemplary embodiment. Differences between the present exemplary embodiment and the sixth exemplary embodiment will be mainly described below. A feature of the present exemplary embodiment is that a second protection circuit and a third protection circuit are disposed on the same component.

FIGS. 20A to 20D are plan views illustrating the semiconductor device according to the seventh exemplary embodiment. The semiconductor device according to the present exemplary embodiment includes a first component 1801, a second component 1802, and a third component 1803 that are stacked in this order as illustrated in FIG. 20A. FIG. 20B illustrates a layout of elements of the first component 1801. A first pad 1804, a first protection circuit 1807, and a first internal circuit 1810 are disposed on the first component 1801. Furthermore, an opening portion is formed that penetrates through the first component 1801 toward a second pad 1805 and a third pad 1806 disposed on the third component 1803. FIG. 20C illustrates a layout of elements of the second component 1802. An opening portion is formed that penetrates through the second component 1802 toward the second pad 1805 and the third pad 1806 disposed on the third component 1803. FIG. 20D illustrates a layout of elements of the third component 1803. The second pad 1805, the third pad 1806, a second protection circuit 1808, a third protection circuit 1809, and a third internal circuit 1812 are disposed on the third component 1803.

FIG. 21 is a sectional view illustrating the semiconductor device taken along a broken line FF′ illustrated in FIGS. 20B to 20D. The components are bonded together through a method similar to that according to the sixth exemplary embodiment as described above, but unlike the sixth exemplary embodiment, the second pad 1805 and the second protection circuit 1808 are disposed on the third component 1803. While the second pad 1805 and the second protection circuit 1808 are both disposed on the third component 1803 in FIG. 21, for example, the second protection circuit 1808 may be disposed on the second component 1802, and the second pad 1805 may be disposed on the third component 1803.

As in the description of the sixth exemplary embodiment, an example of a relationship between voltages to be applied to the components in a case where the SPAD sensor is applied to the semiconductor device according to the present exemplary embodiment will be described below. There is a great difference between the absolute values of voltages to be applied to the first component 1801 and the second component 1802 or between the absolute values of voltages to be applied to the first component 1801 and the third component 1803.

|first power supply voltage|>>|second power supply voltage|>|third power supply voltage|.

The magnitude relationship between the voltages supplied to the substrates can also be expressed as follows:

|first power supply voltage|−|second power supply voltage|>|second power supply voltage−third power supply voltage|, and

|first power supply voltage−third power supply voltage|>|second power supply voltage−third power supply voltage|.

Assume a case where, for example, a voltage of about −30 V is supplied to the first pad 1804, a voltage of about 3.3 V is supplied to the second pad 1805, and a voltage of about 1.1 V is supplied to the third pad 1806. There is not a great difference between the voltage to be supplied to the second pad 1805 and the voltage to be supplied to the third pad 1806, and it is considered that design rules for wiring processes of the second component 1802 and the third component 1803 to which the voltages are supplied from the corresponding pad or dielectric strength of pn junctions of the second component 1802 and the third component 1803 are unlikely to greatly differ from each other. Thus, disposing both of the second pad 1805 and the second protection circuit 1808 on the same substrate is disadvantageous in that it becomes difficult to optimize the pn junctions, trace widths, and spaces, but an influence thereof is small. Meanwhile, the second pad 1805 and the third pad 1806 can be manufactured in the same process.

Since the second protection circuit 1808 and the third protection circuit 1809 can be manufactured in the same process, the semiconductor device according to the seventh exemplary embodiment can be manufactured through fewer process steps than in the sixth exemplary embodiment.

### Eighth Exemplary Embodiment

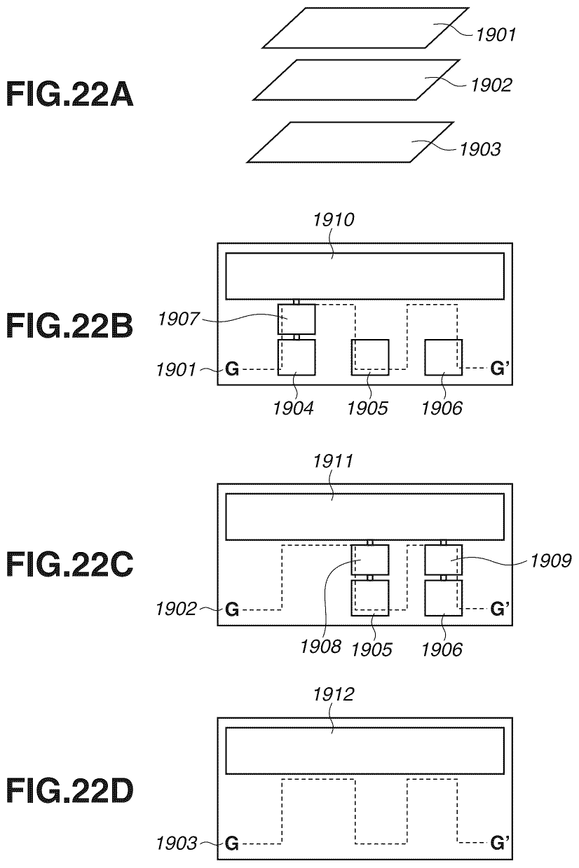

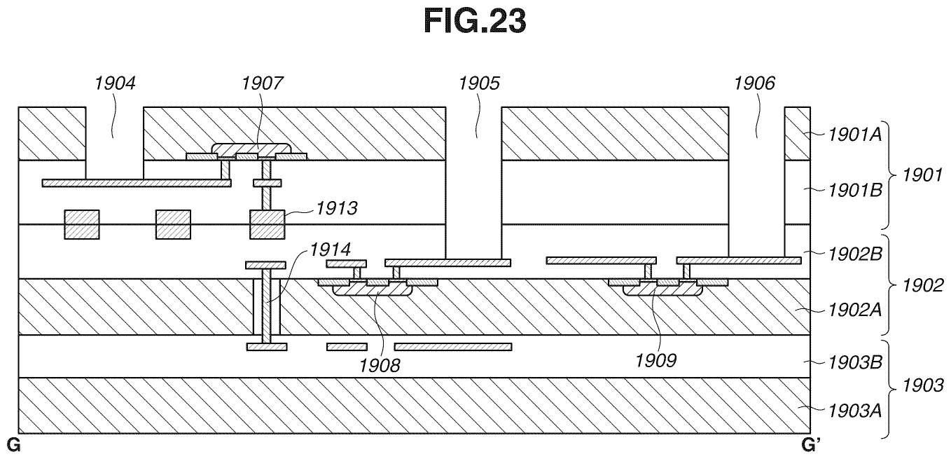

A structure of a semiconductor device according to an eighth exemplary embodiment of the present invention will be described below with reference to FIGS. 22A to 22D and 23. The semiconductor device according to the eighth exemplary embodiment includes three components as in the sixth and seventh exemplary embodiments but has a feature that the components are stacked through a different method.

FIGS. 22A to 22D are plan views illustrating the semiconductor device according to the eighth exemplary embodiment.

According to the present exemplary embodiment, a first component 1901, a second component 1902, and a third component 1903 are stacked in this order as illustrated in FIG. 22A. FIG. 22B illustrates a layout of elements of the first component 1901. A first pad 1904, a first protection circuit 1907, and a first internal circuit 1910 are disposed on the first component 1901. Furthermore, an opening portion is formed that penetrates through the second component 1902 toward a second pad 1905 and a third pad 1906 disposed on the second component 1902. FIG. 22C illustrates a layout of elements of the second component 1902. The second pad 1905, the third pad 1906, and a second internal circuit 1911 are disposed on the second component 1902. As illustrated in FIG. 22D, a third internal circuit 1912 is disposed on the third component 1903 with a pad or a protection element on the third component 1903 not disposed.

FIG. 23 is a sectional view illustrating the semiconductor device taken along a broken line GG′ illustrated in FIGS. 22B to 22D.

According to the present exemplary embodiment, a first wiring layer 1901B and a second wiring layer 1902B are bonded together, and a second semiconductor substrate 1902A and a third wiring layer 1903B are bonded together. The semiconductor device according to the eighth exemplary embodiment includes a first semiconductor substrate 1901A, the first wiring layer 1901B, the second wiring layer 1902B, the second semiconductor substrate 1902A, the third wiring layer 1903B, and a third wiring layer 1903A that are stacked in this order from the top of FIG. 23. The first wiring layer 1901B and the second wiring layer 1902B are electrically connected via, for example, a substrate bonding portion 1913, and the second semiconductor substrate 1902A and the third wiring layer 1903B are electrically connected via, for example, a through-substrate contact portion 1914.

According to the present exemplary embodiment, the first protection circuit 1907 is disposed on the first semiconductor substrate 1901A, and a second protection circuit 1908 and a third protection circuit 1909 are disposed on the second semiconductor substrate 1902A. While, in FIGS. 22A to 22D and 23, the second pad 1905 and the second protection circuit 1908 are disposed in regions that do not overlap with each other in plan view from above a principal surface of the first semiconductor substrate 1901A and the third pad 1906 and the third protection circuit 1909 are disposed in regions that do not overlap with each other in plan view from above the principal surface of the first semiconductor substrate 1901A, these may be disposed in regions that overlap with each other, and the third pad 1906 and the third protection circuit 1909 may be disposed in regions that overlap with each other.

While a deep pad opening is to be formed through a semiconductor substrate at least twice according to the sixth and seventh exemplary embodiments, it is only required that a relatively shallow pad opening is formed through which one of the semiconductor substrates in the semiconductor device according to the present exemplary embodiment. Thus, the present exemplary embodiment makes it possible to simplify pad opening and bonding processes and realize increased reliability.

### Ninth Exemplary Embodiment

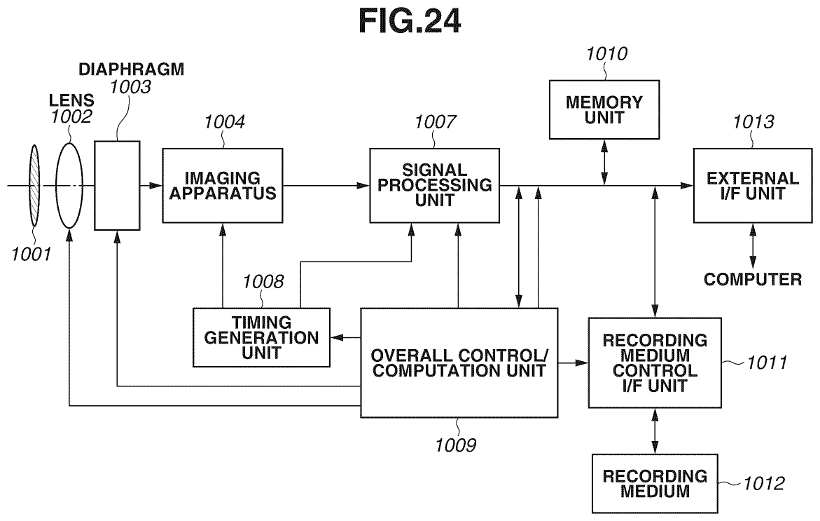

A photoelectric conversion system according to the present exemplary embodiment will be described below with reference to FIG. 24. FIG. 24 is a block diagram illustrating a schematic configuration of the photoelectric conversion system according to the present exemplary embodiment.

The photoelectric conversion apparatuses according to the first to sixth exemplary embodiments are applicable to various photoelectric conversion systems. Examples of applicable photoelectric conversion systems include digital still cameras, digital camcorders, monitoring cameras, copy machines, fax apparatuses, mobile phones, in-vehicle cameras, and observation satellites. A camera module including an optical system such as a lens and an imaging apparatus is also included in the photoelectric conversion systems. FIG. 24 illustrates a block diagram illustrating a digital still camera as an example thereof.

The photoelectric conversion system illustrated as an example in FIG. 24 includes an imaging apparatus 1004 and a lens 1002. The imaging apparatus 1004 is an example of a photoelectric conversion apparatus. The lens 1002 forms an optical image of a subject on the imaging apparatus 1004. The photoelectric conversion system further includes a diaphragm 1003 for adjusting the amount of light passing through the lens 1002 and a barrier 1001 for protecting the lens 1002. The lens 1002 and the diaphragm 1003 are an optical system configured to converge light to the imaging apparatus 1004. The imaging apparatus 1004 is the photoelectric conversion apparatus according to any one of the exemplary embodiments described above and converts an optical image formed by the lens 1002 into an electric signal.

The photoelectric conversion system includes a signal processing unit 1007. The signal processing unit 1007 is an image generation unit configured to generate an image by processing an output signal output from the imaging apparatus 1004. The signal processing unit 1007 performs various types of correction and compression as appropriate and performs an operation of outputting image data. The signal processing unit 1007 may be formed on a semiconductor substrate on which the imaging apparatus 1004 is disposed, or may be formed on another semiconductor substrate different from the imaging apparatus 1004.

The photoelectric conversion system further includes a memory unit 1010 for temporarily storing image data and an external interface unit (external I/F unit) 1013 for communicating with external computers. The photoelectric conversion system further includes a recording medium 1012 such as a semiconductor memory for recording or reading captured data and a recording medium control interface unit (recording medium control I/F unit) 1011 for recording on or reading from the recording medium 1012. The recording medium 1012 may be built in or removable from the photoelectric conversion system.

The photoelectric conversion system further includes an overall control/computation unit 1009 and a timing generation unit 1008. The overall control/computation unit 1009 controls various computations and the entire digital still camera. The timing generation unit 1008 outputs various timing signals to the imaging apparatus 1004 and the signal processing unit 1007. The timing signals may be input from external sources. It is only required that the photoelectric conversion system includes at least the imaging apparatus 1004 and the signal processing unit 1007 configured to process output signals output from the imaging apparatus 1004.

The imaging apparatus 1004 outputs imaging signals to the signal processing unit 1007. The signal processing unit 1007 performs predetermined signal processing on the imaging signals output from the imaging apparatus 1004 and outputs image data. The signal processing unit 1007 generates images using the imaging signals.

As described above, the present exemplary embodiment makes it possible to realize a photoelectric conversion system to which the photoelectric conversion apparatus (imaging apparatus) according to any one of the exemplary embodiments described above is applied.

### Tenth Exemplary Embodiment

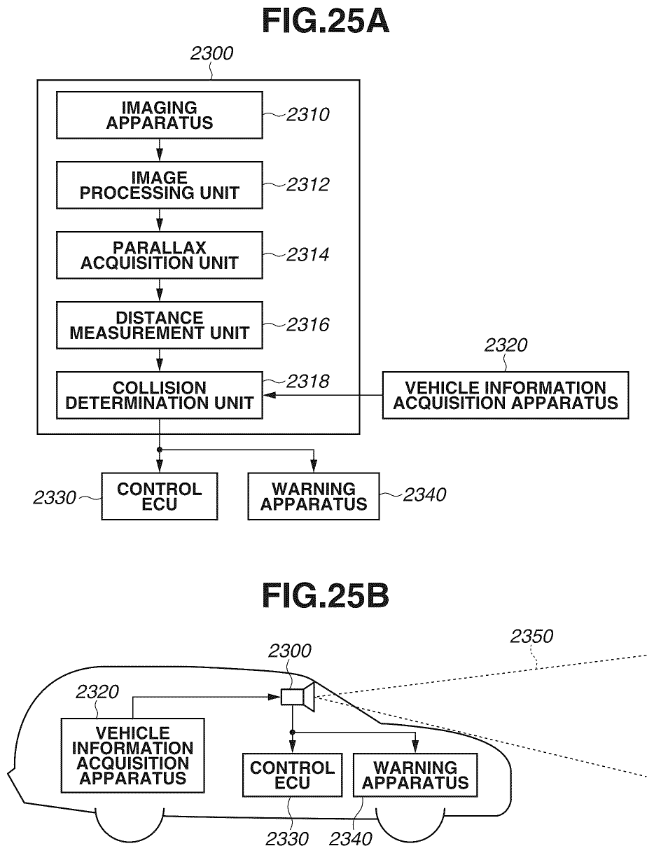

A photoelectric conversion system and a movable object according to the present exemplary embodiment will be described below with reference to FIGS. 25A and 25B. FIGS. 25A and 25B are diagrams illustrating configurations of the photoelectric conversion system and the movable object according to the present exemplary embodiment.

FIG. 25A illustrates an example of a photoelectric conversion system relating to an in-vehicle camera. A photoelectric conversion system 1300 includes an imaging apparatus 1310. The imaging apparatus 1310 is the photoelectric conversion apparatus according to any one of the exemplary embodiments described above. The photoelectric conversion system 1300 includes an image processing unit 1312 and a parallax acquisition unit 1314. The image processing unit 1312 performs image processing on a plurality of image data acquired by the imaging apparatus 1310. The parallax acquisition unit 1314 calculates parallaxes (phase differences of parallax images) from a plurality of image data acquired by the photoelectric conversion system 1300. The photoelectric conversion system 1300 includes a distance acquisition unit 1316 and a collision determination unit 1318. The distance acquisition unit 1316 calculates a distance to a target object based on the calculated parallaxes. The collision determination unit 1318 determines whether there is a possibility of collision based on the calculated distance. The parallax acquisition unit 1314 and the distance acquisition unit 1316 herein are an example of a distance information acquisition unit configured to acquire distance information about a distance to a target object. Specifically, the distance information refers to information about parallaxes, a defocus amount, and a distance to a target object. The collision determination unit 1318 may determine a possibility of collision using any of these pieces of the distance information. The distance information acquisition unit may be realized by dedicated hardware or software modules, such as a field programmable gate array (FPGA), an application specific integrated circuit (ASIC), or a combination thereof.

The photoelectric conversion system 1300 is connected to a vehicle information acquisition apparatus 1320 and can acquire vehicle information, such as vehicle speed, yaw rate, and steering angle. A control engine control unit (control ECU) 1330 is a control unit configured to output control signals for generating braking force on a vehicle based on results of determinations performed by the collision determination unit 1318 and is connected to the photoelectric conversion system 1300. The photoelectric conversion system 1300 is also connected to a warning apparatus 1340. The warning apparatus 1340 issues warnings to a driver based on results of the determinations performed by the collision determination unit 1318. For example, in a case where the collision determination unit 1318 determines that there is a high possibility of collision, the control ECU 1330 performs vehicle control to avoid a collision or reduce damage by applying a brake, releasing an accelerator, or suppressing engine output. The warning apparatus 1340 issues a warning to the user by sounding a warning, such as a sound, displaying warning information on a screen of a car navigation system, or applying a vibration to a seat belt or steering.

According to the present exemplary embodiment, the photoelectric conversion system 1300 captures images around a vehicle, for example, images of the front or rear of the vehicle. FIG. 25B illustrates a photoelectric conversion system in a case of capturing images of the front of the vehicle (imaging range 1350). The vehicle information acquisition apparatus 1320 transmits instructions to the photoelectric conversion system 1300 or the imaging apparatus 1310. Such a configuration further improves distance measurement accuracy.

While the control for avoiding collision with other vehicles is described above as an example, application to other controls, such as a control for automated driving following other vehicles or a control for automated driving to stay within a lane, is also possible. The photoelectric conversion system is further applicable to not only vehicles, such as automobiles, but also movable objects (movable apparatuses), such as ships, aircraft, or industrial robots. Furthermore, application is not limited to movable objects, and application to equipment using object recognition widely, such as an Intelligent Transportation System (ITS), is also possible.

### Eleventh Exemplary Embodiment

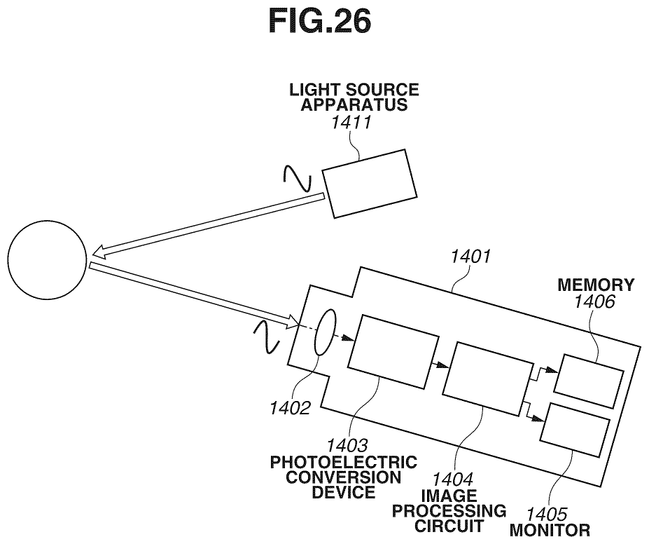

A photoelectric conversion system according to the present exemplary embodiment will be described below with reference to FIG. 26. FIG. 26 is a block diagram illustrating an example of a configuration of a distance image sensor of the photoelectric conversion system according to the present exemplary embodiment.

As illustrated in FIG. 26, a distance image sensor 1401 includes an optical system 1407, a photoelectric conversion device 1408, an image processing circuit 1404, a monitor 1405, and a memory 1406. The distance image sensor 1401 is capable of acquiring a distance image based on a distance to a subject by receiving light (modulated light, pulse light) emitted from a light source apparatus 1409 to the subject and reflected by a surface of the subject.

The optical system 1407 includes one or more lenses, guides image light (incident light) from a subject to the photoelectric conversion device 1408, and forms an image on a light-receiving surface (sensor portion) of the photoelectric conversion device 1408.

The photoelectric conversion apparatus according to any one of the exemplary embodiments described above is applied as the photoelectric conversion device 1408, and a distance signal indicating a distance obtained from a received light signal output from the photoelectric conversion device 1408 is supplied to the image processing circuit 1404.

The image processing circuit 1404 performs image processing to construct a distance image based on the distance signal supplied from the photoelectric conversion device 1408. The distance image (image data) obtained through the image processing is supplied to the monitor 1405 and displayed on the monitor 1405 or is supplied to the memory 1406 and stored (recorded) in the memory 1406.

Application of the photoelectric conversion apparatus described above to the distance image sensor 1401 having the configuration described above improves pixel characteristics, and this makes it possible to, for example, acquire more accurate distance images.

### Twelfth Exemplary Embodiment

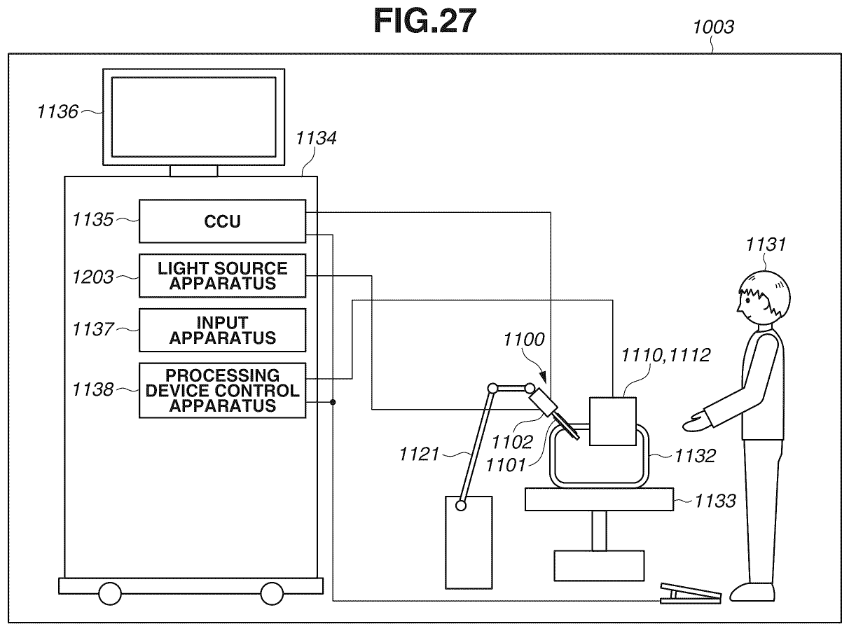

A photoelectric conversion system according to the present exemplary embodiment will be described below with reference to FIG. 27. FIG. 27 is a diagram illustrating an example of a schematic configuration of an endoscopic surgery system that is the photoelectric conversion system according to the present exemplary embodiment.

FIG. 27 illustrates an operator (doctor) 1131 performing surgery on a patient 1132 on a patient bed 1133 using an endoscopic surgery system 1150. As illustrated, the endoscopic surgery system 1150 includes an endoscope 1100, a surgical instrument 1110, and a cart 1134 in which various apparatuses for endoscopic surgery are installed.

The endoscope 1100 includes a tube 1101 and a camera head 1102. A portion of a predetermined length from a tip of the tube 1101 is inserted into a body cavity of the patient 1132. The camera head 1102 is to be connected to a proximal end of the tube 1101. While the endoscope 1100 configured as a so-called rigid scope including the rigid tube 1101 is illustrated as an example, the endoscope 1100 may be configured as a so-called flexible scope including a flexible tube.

The tip of the tube 1101 includes an opening portion in which an objective lens is fitted. A light source apparatus 1203 is connected to the endoscope 1100, and light generated by the light source apparatus 1203 is guided to the tip of the tube by a light guide extending inside the tube 1101 and irradiates an observation target in the body cavity of the patient 1132 through an objective lens. The endoscope 1100 may be a forward-viewing endoscope, a forward-oblique viewing endoscope, or a side viewing endoscope.

An optical system and a photoelectric conversion apparatus are disposed inside the camera head 1102, and reflected light (observation light) from the observation target is condensed to the photoelectric conversion apparatus by the optical system. Observation light is photoelectrically converted by the photoelectric conversion apparatus, and electric signals corresponding to the observation light, specifically image signals corresponding to an observation image, is generated. The photoelectric conversion apparatus according to any one of the exemplary embodiments described above is useable as the photoelectric conversion apparatus. The image signal is transmitted as RAW data to a camera control unit (CCU) 1135.

The CCU 1135 includes a central processing unit (CPU) and/or a graphics processing unit (GPU) and comprehensively controls operations of the endoscope 1100 and a display apparatus 1136. Furthermore, the CCU 1135 receives image signals from the camera head 1102 and performs various types of image processing, such as development processing (demosaicing processing), on the image signals to display an image based on the image signals.

The display apparatus 1136 displays an image based on the image signals having undergone the image processing under control of the CCU 1135.

The light source apparatus 1203 includes a light source such as a light emitting diode (LED) and supplies irradiation light to the endoscope 1100 in imaging a surgical site.

An input apparatus 1137 is an input interface for the endoscopic surgery system 1150. A user can input various types of information and instructions to the endoscopic surgery system 1150 via the input apparatus 1137.

A treatment device control apparatus 1138 controls the driving of an energy treatment device 1112 for ablation or incision of tissue, or sealing of blood vessels.

The light source apparatus 1203 that supplies irradiation light to the endoscope 1100 in surgical site imaging may include a white light source including, for example, an LED, a laser light source, or a combination thereof. In a case where the white light source includes a combination of red (R) green (G) blue (B) (RGB) laser light sources, an output intensity and an output timing of each color (each wavelength) are controllable with high accuracy, so that the light source apparatus 1203 performs white balance adjustment on captured images. In this case, an observation target is irradiated with laser light from each RGB laser light source with time division and the driving of an image sensor of the camera head 1102 is controlled in synchronization with the irradiation timing, thus capturing an image for each RGB color. This method makes it possible to acquire color images with color filters not disposed on the image sensor.

The driving of the light source apparatus 1203 may be controlled so that the output light intensity is changed at predetermined time intervals. Driving of the image sensor of the camera head 1102 is controlled in synchronization with the light intensity change timing to acquire images with time division and the images are synthesized, thus generating a so-called high dynamic range image without underexposure and overexposure.

The light source apparatus 1203 may be configured to supply light of a predetermined wavelength range for a specific light observation. In the specific light observation, for example, the wavelength dependence of light absorption in body tissue is used. Specifically, predetermined tissue such as blood vessels in a superficial portion of the mucous membrane is irradiated with light with a narrower band than that in the irradiation light (i.e., white light) in normal observation, thus imaging the tissue with high contrast. Alternatively, in the specific light observation, a fluorescence observation may be performed to acquire images using fluorescence generated by irradiation with excitation light. In the fluorescence observation, body tissue is irradiated with excitation light and fluorescence from the body tissue is observed, or a reagent such as indocyanine green (ICG) is locally injected into body tissue and the body tissue is irradiated with excitation light corresponding to the fluorescence wavelength of the reagent to thereby acquire a fluorescence image. The light source apparatus 1203 may be configured to supply narrowband light and/or excitation light for the specific light observation.

### Thirteenth Exemplary Embodiment

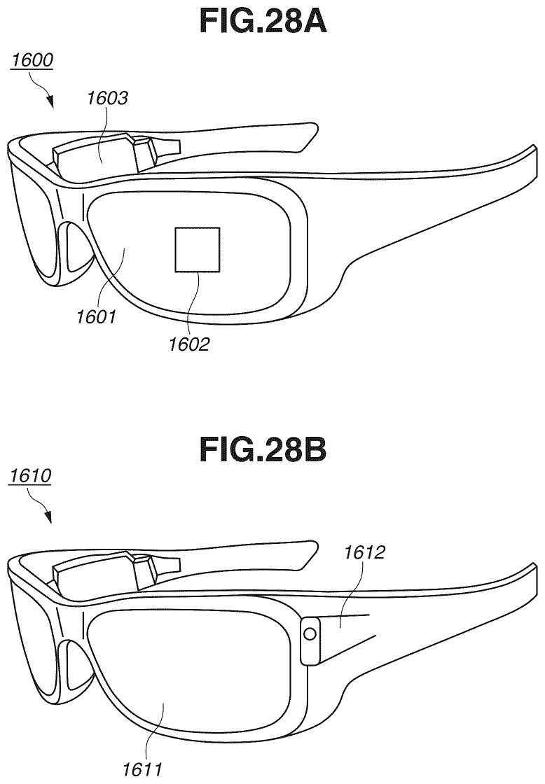

A photoelectric conversion system according to the present exemplary embodiment will be described below with reference to FIGS. 28A and 28B. FIG. 28A illustrates glasses 1600 (smart glasses) that are the photoelectric conversion system according to the present exemplary embodiment. The glasses 1600 include a photoelectric conversion apparatus 1602. The photoelectric conversion apparatus 1602 is a photoelectric conversion apparatus according to any one of the exemplary embodiments described above. A display apparatus including a light emitting device such as an organic LED (OLED) or a LED may be disposed on the back side of a lens lens 1601. There may be one or more photoelectric conversion apparatuses 1602. A plurality of types of photoelectric conversion apparatuses may be used in combination. The position of the photoelectric conversion apparatus 1602 is not limited to that in FIG. 28A.

The glasses 1600 further includes a control apparatus 1603. The control apparatus 1603 functions as a power supply that supplies power to the photoelectric conversion apparatus 1602 and the display apparatus. The control apparatus 1603 controls operations of the photoelectric conversion apparatus 1602 and the display apparatus. An optical system for converging light to the photoelectric conversion apparatus 1602 is formed on the lens 1601.

FIG. 28B illustrates glasses 1610 (smart glasses) according to one application example. The glasses 1610 include a control apparatus 1612, and the control apparatus 1612 includes a display apparatus and a photoelectric conversion apparatus equivalent to the photoelectric conversion apparatus 1602. A lens 1611 includes the photoelectric conversion apparatus in the control apparatus 1612 and an optical system for projecting light emission from the display apparatus, and images are projected to the lens 1611. The control apparatus 1612 functions as a power supply that supplies power to the photoelectric conversion apparatus and the display apparatus, and controls operations of the photoelectric conversion apparatus and the display apparatus. The control apparatus may include a line of sight detection unit configured to detect a line of sight of a wearer. Infrared radiation may be used in the line of sight detection. An infrared light emitting unit emits infrared light to an eyeball or the eyeballs of a user gazing at a display image. An imaging unit including light receiving elements detects the emitted infrared light reflected from the eyeball(s) is detected, thus obtaining captured images of the eyeball(s). Including a reduction unit configured to reduce light from the infrared light emitting unit to a display unit in plan view reduces image quality loss.

The line of sight of the user on the display image is detected from the captured eyeball images obtained through infrared imaging. A publicly-known method is applicable to the line of sight detection using captured eyeball images. For example, a line of sight detection method based on Purkinje images from reflections of irradiation light from the cornea may be used.

More specifically, line of sight detection processing based on a pupil center corneal reflection method is performed. The line of sight vectors representing directions (rotation angles) of the eyeball(s) are calculated using the pupil center corneal reflection method based on pupil images and Purkinje images in the captured eyeball images, thus detecting the line of sight of the user.

The display apparatus according to the present exemplary embodiment may include a photoelectric conversion apparatus including a light receiving element, and a display image on the display apparatus may be controlled based on user line of sight information from the photoelectric conversion apparatus.

Specifically, the display apparatus determines, based on the line of sight information, a first field-of-view region at which the user is gazing and a second field-of-view region other than the first field-of-view region. The first field-of-view region and the second field-of-view region may be determined by a control apparatus of the display apparatus, or a first field-of-view region and a second field-of-view region that are determined by an external control apparatus may be received. In a display region of the display apparatus, the first field-of-view region may be controlled to be higher in display resolution than the second field-of-view region. Specifically, the resolution of the second field-of-view region may be set lower than the resolution of the first field-of-view region.

The display region includes a first display region and a second display region different from the first display region, and a region with high priority may be determined from the first display region and the second display region based on the line of sight information. The first field-of-view region and the second field-of-view region may be determined by the control apparatus of the display apparatus, or a first field-of-view region and a second field-of-view region that are determined by an external control apparatus may be received. The region with high priority may be controlled to be higher in resolution than the region other than the region with high priority. Specifically, the resolution of the region with relatively low priority may be set low.

Artificial intelligence (AI) may be used to determine the first field-of-view region and the region with high priority. The AI may be a model configured to estimate, from eyeball images, an angle of the line of sight and a distance to an object present along the line of sight using the eyeball images and the direction of the actual lines of sights of the eyeballs in the images as training data. AI programs may be included in the display apparatus, the photoelectric conversion apparatus, or an external apparatus. In a case where an external apparatus includes the AI programs, the AI programs are transmitted to the display apparatus via communication.

In a case where display control is performed based on visual detection, smart glasses further including a photoelectric conversion apparatus configured to image an external environment is appropriately applicable. The smart glasses are capable of displaying captured external information in real time.

### Modified Exemplary Embodiments

The present invention is not limited to the exemplary embodiments described above, and various modifications are possible.

For example, an example in which a portion of a configuration according to an exemplary embodiment is added to another exemplary embodiment and an example in which a portion of a configuration according to an exemplary embodiment is replaced with a portion of a configuration according to another exemplary embodiment are also included in the exemplary embodiments of the present invention.

The photoelectric conversion systems according to the ninth and tenth exemplary embodiments are mere examples of photoelectric conversion systems to which a photoelectric conversion apparatus is applicable, and photoelectric conversion systems to which the photoelectric conversion apparatuses according to the present invention are applicable are not limited to the configurations illustrated in FIGS. 24 to 25B. A similar applies to a Time-of-Flight (ToF) system according to the eleventh exemplary embodiment, the endoscope according to the twelfth exemplary embodiment, and the smart glasses according to the thirteenth exemplary embodiment.

The exemplary embodiments described above are mere examples of concretization in implementing the present invention, and the technical scope of the present invention should not be interpreted narrowly by the exemplary embodiments. Specifically, the present invention can be implemented in various forms without departing from the technical idea or key features of the present invention.

The present disclosure includes the following configurations.

### (Configuration 1)

A semiconductor device including a first semiconductor substrate, a second semiconductor substrate stacked on the first semiconductor substrate, a first pad to which a first power supply voltage for driving an element on the first semiconductor substrate is externally input, a second pad to which a second power supply voltage for driving an element on the second semiconductor substrate is externally input, a first protection circuit disposed on the first semiconductor substrate, and a second protection circuit disposed on the second semiconductor substrate, wherein the first power supply voltage is higher than the second power supply voltage, wherein the first protection circuit is electrically connected to the first pad, and wherein the second protection circuit is electrically connected to the second pad.

### (Configuration 2)

The semiconductor device according to Configuration 1, wherein the first protection circuit is larger in circuit area than the second protection circuit.

### (Configuration 3)

The semiconductor device according to configuration 1 or 2, wherein a gate oxide film of a transistor included in the first protection circuit is thicker than a gate oxide film of a transistor included in the second protection circuit.

### (Configuration 4)

The semiconductor device according to any one of Configurations 1 to 3, wherein the first protection circuit and the second protection circuit do not overlap in plan view.

### (Configuration 5)

The semiconductor device according to any one of Configurations 1 to 4, further including a first wiring structure between the first semiconductor substrate and the second semiconductor substrate, a second wiring structure between the first wiring structure and the second semiconductor substrate, a first wiring layer included in the first wiring structure, and a second wiring layer included in the second wiring structure.

### (Configuration 6)

The semiconductor device according to Configuration 5, wherein the first pad and the second pad are disposed on the same layer as the first wiring layer.

### (Configuration 7)

The semiconductor device according to Configuration 5, wherein the first pad is disposed on the same layer as the first wiring layer, and wherein the second pad is disposed on the same layer as the second wiring layer.

### (Configuration 8)

The semiconductor device according to Configuration 6 or 7, wherein a second opening portion is formed above a portion of the second wiring layer.

### (Configuration 9)

The semiconductor device according to any one of Configurations 5 to 8, wherein the first wiring structure includes a first insulation layer, wherein the second wiring structure includes a second insulation layer, and wherein the first wiring structure and the second wiring structure are bonded together so that the first insulation layer and the second insulation layer are in contact with each other.

### (Configuration 10)

The semiconductor device according to any one of Configurations 5 to 9, wherein a first wiring included in the first wiring trace is electrically connected to the element on the first semiconductor substrate.

### (Configuration 11)

The semiconductor device according to any one of Configurations 5 to 10, wherein a second trace included in the second wiring layer is electrically connected to the element on the second semiconductor substrate.

### (Configuration 12)

The semiconductor device according to any one of Configurations 1 to 11, wherein the first protection circuit is electrically connected between the first pad and a reference potential trace, and wherein the second protection circuit is electrically connected between the second pad and the reference potential trace.

### (Configuration 13)

The semiconductor device according to Configuration 12, wherein the reference potential trace is a trace of ground wiring.

### (Configuration 14)

The semiconductor device according to Configuration 12 or 13, wherein the reference potential trace is formed on either the first semiconductor substrate or the second semiconductor substrate.

### (Configuration 15)

The semiconductor device according to any one of Configurations 1 to 14, wherein the element on the first semiconductor substrate includes a photoelectric conversion element.

### (Configuration 16)

The semiconductor device according to Configuration 15, wherein the first semiconductor substrate includes at least part of a circuit for reading a signal based on charge of the photoelectric conversion element.

### (Configuration 17)

The semiconductor device according to Configuration 15, wherein the photoelectric conversion element is an avalanche photodiode to which the first power supply voltage is input.

### (Configuration 18)

The semiconductor device according to any one of Configurations 1 to 17, wherein the first semiconductor substrate is thinner than the second semiconductor substrate.

### (Configuration 19)

The semiconductor device according to Configuration 5, wherein the number of wiring layers disposed between the first protection circuit and a wiring layer on which the first pad is disposed is less than or equal to the number of wiring layers disposed between the second protection circuit and wiring layer on which the second pad is disposed.

### (Configuration 20)

The semiconductor device according to Configuration 1, further including a third semiconductor substrate stacked on the second semiconductor substrate, a third pad to which a third power supply voltage for driving an element on the third semiconductor substrate is externally input, and a third protection circuit to be electrically connected to the third pad, wherein the first power supply voltage is greater in absolute value than the third power supply voltage.

### (Configuration 21)

The semiconductor device according to Configuration 20, further including a first wiring structure stacked on the first semiconductor substrate, a second wiring structure stacked on the second semiconductor substrate, a third wiring structure stacked on the third semiconductor substrate, a first wiring layer included in the first wiring structure, a second wiring layer included in the second wiring structure, and a third wiring layer included in the third wiring structure, wherein the first pad is disposed on the same layer as the first wiring layer, wherein the second pad is disposed on the same layer as the second wiring layer, and wherein the third pad is disposed on the same layer as the third wiring layer.

### (Configuration 22)

The semiconductor device according to Configuration 20, further including a first wiring structure stacked on the first semiconductor substrate, a second wiring structure stacked on the second semiconductor substrate, a third wiring structure stacked on the third semiconductor substrate, a first wiring layer included in the first wiring structure, a second wiring layer included in the second wiring structure, and a third wiring layer included in the third wiring structure, wherein the first pad is disposed on the same layer as the first wiring layer, and wherein the second pad and the third pad are disposed on the same layer as the second wiring layer

### (Configuration 23)

A photoelectric conversion system including the semiconductor device according to any one of Configurations 1 to 22, and a signal processing unit configured to generate an image using a signal output from the semiconductor device.

### (Configuration 24)

A movable object including the semiconductor device according to any one of Configurations 1 to 22, the movable object further including a control unit configured to control movement of the movable object using a signal output from the semiconductor device.

The present invention is not limited to the exemplary embodiments described above, and various changes and modifications can be made without departing from the spirit and scope of the present invention. Accordingly, the following claims are attached to disclose the scope of the present invention.

This application claims priority to Japanese Patent Application No. 2021-208537 filed Dec. 22, 2021 and Japanese Patent Application No. 2022-188492 filed Nov. 25, 2022, which are incorporated herein by reference in their entirety.

The present invention makes it possible to provide a protection circuit suitable for elements of each substrate of a semiconductor device configured by layering the substrates disposed with the elements driven by different voltages from each other.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A semiconductor device comprising:
a first semiconductor substrate;
a second semiconductor substrate stacked on the first semiconductor substrate;
a first pad to which a first power supply voltage for driving an element on the first semiconductor substrate is externally input;
a second pad to which a second power supply voltage for driving an element on the second semiconductor substrate is externally input;
a first protection circuit disposed on the first semiconductor substrate; and
a second protection circuit disposed on the second semiconductor substrate,
wherein the first power supply voltage is higher than the second power supply voltage,
wherein the first protection circuit is electrically connected to the first pad, and
wherein the second protection circuit is electrically connected to the second pad.

2. The semiconductor device according to claim 1, wherein the first protection circuit is larger in circuit area than the second protection circuit.

3. The semiconductor device according to claim 1, wherein a gate oxide film of a transistor included in the first protection circuit is thicker than a gate oxide film of a transistor included in the second protection circuit.

4. The semiconductor device according to claim 1, wherein the first protection circuit and the second protection circuit do not overlap in plan view.

5. The semiconductor device according to claim 1, further comprising:
a first wiring structure between the first semiconductor substrate and the second semiconductor substrate;
a second wiring structure between the first wiring structure and the second semiconductor substrate;
a first wiring layer included in the first wiring structure; and
a second wiring layer included in the second wiring structure.

6. The semiconductor device according to claim 5, wherein the first pad and the second pad are disposed on the same layer as the first wiring layer.

7. The semiconductor device according to claim 5,
wherein the first pad is disposed on the same layer as the first wiring layer, and
wherein the second pad is disposed on the same layer as the second wiring layer.

8. The semiconductor device according to claim 6, wherein a second opening portion is disposed above a portion of the second wiring layer.

9. The semiconductor device according to claim 5,
wherein the first wiring structure includes a first insulation layer,
wherein the second wiring structure includes a second insulation layer, and
wherein the first wiring structure and the second wiring structure are bonded together so that the first insulation layer and the second insulation layer are in contact with each other.

10. The semiconductor device according to claim 5, wherein a first trace included in the first wiring layer is electrically connected to the element on the first semiconductor substrate.

11. The semiconductor device according to claim 5, wherein a second trace included in the second wiring layer is electrically connected to the element on the second semiconductor substrate.

12. The semiconductor device according to claim 1,
wherein the first protection circuit is electrically connected between the first pad and a reference potential trace, and
wherein the second protection circuit is electrically connected between the second pad and the reference potential trace.

13. The semiconductor device according to claim 12, wherein the reference potential trace is a trace of ground wiring.

14. The semiconductor device according to claim 12, wherein the reference potential trace is disposed on either the first semiconductor substrate or the second semiconductor substrate.

15. The semiconductor device according to claim 1, wherein the element on the first semiconductor substrate includes a photoelectric conversion element.

16. The semiconductor device according to claim 15, wherein the first semiconductor substrate includes at least part of a circuit for reading a signal based on charge of the photoelectric conversion element.

17. The semiconductor device according to claim 15, wherein the photoelectric conversion element is an avalanche photodiode to which the first power supply voltage is input.

18. The semiconductor device according to claim 1, wherein the first semiconductor substrate is thinner than the second semiconductor substrate.

19. The semiconductor device according to claim 5, wherein the number of wiring layers disposed between the first protection circuit and a wiring layer on which the first pad is disposed is less than or equal to the number of wiring layers disposed between the second protection circuit and wiring layer on which the second pad is disposed.

20. The semiconductor device according to claim 1, further comprising:
a third semiconductor substrate stacked on the second semiconductor substrate;
a third pad to which a third power supply voltage for driving an element on the third semiconductor substrate is externally input; and
a third protection circuit to be electrically connected to the third pad,
wherein the first power supply voltage is greater in absolute value than the third power supply voltage.

21. The semiconductor device according to claim 20, further comprising;
a first wiring structure stacked on the first semiconductor substrate;
a second wiring structure stacked on the second semiconductor substrate;
a third wiring structure stacked on the third semiconductor substrate;
a first wiring layer included in the first wiring structure;
a second wiring layer included in the second wiring structure; and
a third wiring layer included in the third wiring structure,
wherein the first pad is disposed on the same layer as the first wiring layer,
wherein the second pad is disposed on the same layer as the second wiring layer, and
wherein the third pad is disposed on the same layer as the third wiring layer.

22. The semiconductor device according to claim 20, further comprising;
a first wiring structure stacked on the first semiconductor substrate;
a second wiring structure stacked on the second semiconductor substrate;
a third wiring structure stacked on the third semiconductor substrate;
a first wiring layer included in the first wiring structure;
a second wiring layer included in the second wiring structure; and
a third wiring layer included in the third wiring structure,
wherein the first pad is disposed on the same layer as the first wiring layer, and
wherein the second pad and the third pad are disposed on the same layer as the second wiring layer.

23. A photoelectric conversion system comprising:
the semiconductor device according to claim 1; and
a signal processing unit configured to generate an image using a signal output from the semiconductor device.

24. A movable object including the semiconductor device according to claim 1, the movable object comprising a control unit configured to control movement of the movable object using a signal output from the semiconductor device.
